(19) United States
(12) Patent Application Publication
(10) Pub. No.: US 2025/0318223 A1
(43) Pub. Date: Oct. 9, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takuya YASUTAKE, Kanazawa Ishikawa (JP); Saya FUJINO, Kanazawa Ishikawa (JP); Tsuyoshi KACHI, Kanazawa Ishikawa (JP); Hiroaki KATOU, Nonoichi Ishikawa (JP); Kazuyuki SATO, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/892,654

(22) Filed: Sep. 23, 2024

(30) Foreign Application Priority Data
Apr. 8, 2024 (JP) 2024-062097

(51) Int. Cl. H01L 29/08; H01L 29/06; H01L 29/40; H01L 29/78

(52) U.S. Cl. CPC H10D 62/155; H10D 30/665; H10D 30/668; H10D 62/127; H10D 64/117

(57) ABSTRACT

A semiconductor device according to an embodiment includes: a semiconductor layer; a first and gate electrode extending in a first direction; a second gate electrode extending in the first direction; a first electrode provided on the semiconductor layer; and a second electrode provided on opposites side of the semiconductor layer. The first electrode includes a first portion and a second portion, the first portion and the second portion are provided between the first gate electrode and the second gate electrode, the first portion and the second portion are in contact with the semiconductor layer, the second portion is in the first direction with respect to the first portion, and a second width of the second portion is larger than a first width of the first portion, or a second depth of the second portion is larger than a first depth of the first portion.

### CROSS-REFERENCE TO RELATED APPLICATION

This application is based upon and claims the benefit of priority from Japanese Patent Application No. 2024-062097, filed on Apr. 8, 2024, the entire contents of which are incorporated herein by reference.

### FIELD

Embodiments described herein relate generally to a semiconductor device.

### BACKGROUND

An example of a power semiconductor device is a metal oxide semiconductor field effect transistor (MOSFET). In the MOSFET, improvement in avalanche capability is desired.

### BRIEF DESCRIPTION OF THE DRAWINGS

FIGS. 1A and 1B are schematic views of a semiconductor device according to a first embodiment;

FIG. 2 is a schematic cross-sectional view of a part of the semiconductor device according to the first embodiment;

FIG. 3 is a schematic top view of a part of the semiconductor device according to the first embodiment;

FIG. 4 is a schematic cross-sectional view of a part of the semiconductor device according to the first embodiment;

FIG. 5 is a schematic cross-sectional view of a part of a semiconductor device according to a comparative embodiment;

FIG. 6 is a schematic top view of a part of the semiconductor device according to the comparative embodiment;

FIG. 7 is a schematic cross-sectional view of a part of a semiconductor device according to a first modified example of the first embodiment;

FIG. 8 is a schematic top view of a part of the semiconductor device according to the first modified example of the first embodiment;

FIG. 9 is a schematic top view of a part of a semiconductor device according to a second modified example of the first embodiment;

FIG. 10 is a schematic cross-sectional view of a part of a semiconductor device according to a third modified example of the first embodiment;

FIG. 11 is a schematic cross-sectional view of a part of a semiconductor device according to a fourth modified example of the first embodiment;

FIG. 12 is a schematic cross-sectional view of a part of a semiconductor device according to a fifth modified example of the first embodiment;

FIG. 13 is a schematic cross-sectional view of a part of a semiconductor device according to a second embodiment;

FIG. 14 is a schematic top view of a part of the semiconductor device according to the second embodiment;

FIG. 15 is a schematic cross-sectional view of a part of the semiconductor device according to the second embodiment;

FIG. 16 is a schematic cross-sectional view of a part of the semiconductor device according to the second embodiment;

FIG. 17 is a schematic cross-sectional view of a part of a semiconductor device according to a first modified example of the second embodiment;

FIG. 18 is a schematic top view of a part of the semiconductor device according to the first modified example of the second embodiment;

FIG. 19 is a schematic cross-sectional view of a part of a semiconductor device according to a second modified example of the second embodiment;

FIGS. 20A and 20B are schematic views of a semiconductor device according to a third embodiment;

FIG. 21 is a schematic top view of a part of the semiconductor device according to the third embodiment;

FIG. 22 is a schematic top view of a part of the semiconductor device according to the third embodiment;

FIG. 23 is a schematic cross-sectional view of a part of the semiconductor device according to the third embodiment;

FIG. 24 is a schematic cross-sectional view of a part of the semiconductor device according to the third embodiment;

FIG. 25 is a schematic top view of a part of a semiconductor device according to a first modified example of the third embodiment;

FIG. 26 is a schematic cross-sectional view of a part of the semiconductor device according to the first modified example of the third embodiment;

FIG. 27 is a schematic cross-sectional view of a part of the semiconductor device according to the first modified example of the third embodiment;

FIG. 28 is a schematic cross-sectional view of a part of the semiconductor device according to the first modified example of the third embodiment;

FIGS. 29A and 29B are schematic views of a semiconductor device according to a fourth embodiment;

FIG. 30 is a schematic top view of a part of the semiconductor device according to the fourth embodiment;

FIG. 31 is a schematic top view of a part of the semiconductor device according to the fourth embodiment;

FIG. 32 is a schematic cross-sectional view of a part of the semiconductor device according to the fourth embodiment;

FIG. 33 is a schematic top view of a part of a semiconductor device according to a first modified example of the fourth embodiment; and

FIG. 34 is a schematic cross-sectional view of a part of the semiconductor device according to the first modified example of the fourth embodiment.

### DETAILED DESCRIPTION

A semiconductor device according to an embodiment includes: a semiconductor layer having a first face and a second face facing the first face, and including a first semiconductor region of a first conductivity type, a second semiconductor region of a second conductivity type provided between the first semiconductor region and the first face, and a third semiconductor region of the first conductivity type provided between the second semiconductor region and the first face; a first gate electrode provided on a first face side of the semiconductor layer and extending in a first direction parallel to the first face; a second gate electrode provided on the first face side of the semiconductor layer and extending in the first direction, and provided in a second direction parallel to the first face and perpendicular to the first direction with respect to the first gate electrode; a first gate insulating layer provided between the first gate electrode and the semiconductor layer; a second gate insulating layer provided between the second gate electrode and the semiconductor layer; a first electrode provided on the first face side of the semiconductor layer and electrically connected to the third semiconductor region; and a second electrode provided on a second face side of the semiconductor layer and electrically connected to the first semiconductor region, wherein the first electrode includes a first portion and a second portion, the first portion and the second portion are provided between the first gate electrode and the second gate electrode, the first portion and the second portion are in contact with the second semiconductor region, the second portion is provided in the first direction with respect to the first portion, the first portion is sandwiched between a part and another part of the semiconductor layer in the second direction, the second portion is sandwiched between a part and another part of the semiconductor layer in the second direction, and a second width of the second portion in the second direction is larger than a first width of the first portion in the second direction, or a second depth of the second portion is larger than a first depth of the first portion.

Hereinafter, embodiments of the present disclosure will be described with reference to the drawings. In the following description, the same or similar members and the like are denoted by the same reference numerals, and the description of the members and the like once described is appropriately omitted.

In the present specification, in a case where there are notations of n⁺ type, n type, and n-type, it means that an n type impurity concentration decreases in the order of n⁺ type, n type, and n-type. In addition, in a case where there are notations of p⁺ type, p type, and p-type, it means that a p type impurity concentration decreases in the order of p⁺ type, p type, and p-type.

An impurity concentration of the semiconductor device can be measured by, for example, secondary ion mass spectrometry (SIMS). A relative level of the impurity concentration of the semiconductor device can also be determined from, for example, a level of a carrier concentration obtained by scanning capacitance microscopy (SCM). Furthermore, a distance such as a width or depth of an impurity region of the semiconductor device can be obtained by, for example, SIMS. Alternatively, the distance such as the width or depth of the impurity region of the semiconductor device can be obtained from, for example, an SCM image.

Qualitative analysis and quantitative analysis of a chemical composition of a member included in the semiconductor device in the present specification can be performed by, for example, SIMS, energy dispersive X-ray spectroscopy (EDX), and Rutherford back-scattering spectrometry (RBS). For example, a scanning electron microscope (SEM) or a transmission electron microscope (TEM) can be used for measuring a thickness of a member included in the semiconductor device, a distance between the members, and the like.

### First Embodiment

A semiconductor device according to a first embodiment includes: a semiconductor layer having a first face and a second face facing the first face, and including a first semiconductor region of a first conductivity type, a second semiconductor region of a second conductivity type provided between the first semiconductor region and the first face, and a third semiconductor region of the first conductivity type provided between the second semiconductor region and the first face; a first gate electrode provided on a side of the semiconductor layer and extending in a first direction parallel to the first face, the side being adjacent to the first face; a second gate electrode provided on the side of the semiconductor layer, extending in the first direction, and provided in a second direction parallel to the first face and perpendicular to the first direction with respect to the first gate electrode, the side being adjacent to the first face; a first gate insulating layer provided between the first gate electrode and the semiconductor layer; a second gate insulating layer provided between the second gate electrode and the semiconductor layer; a first electrode provided on the side of the semiconductor layer and electrically connected to the third semiconductor region, the side being adjacent to the first face; and a second electrode provided on a side of the semiconductor layer and electrically connected to the first semiconductor region, the side being adjacent to the second face. The first electrode includes a first portion and a second portion, the first portion and the second portion are provided between the first gate electrode and the second gate electrode, the first portion and the second portion are in contact with the second semiconductor region, the second portion is provided in the first direction with respect to the first portion, the first portion is sandwiched between a part and another part of the semiconductor layer in the second direction, the second portion is sandwiched between a part and another part of the semiconductor layer in the second direction, and a second width of the second portion in the second direction is larger than a first width of the first portion in the second direction.

The semiconductor layer further includes a first trench provided on the side adjacent to the first face and extending in the first direction, and a second trench provided on the side adjacent to the first face and extending in the first direction. The first gate electrode is provided in the first trench, and the second gate electrode is provided in the second trench.

The semiconductor device according to the first embodiment further includes: a first field plate electrode provided in the first trench and provided between the first gate electrode and the second face; a second field plate electrode provided in the second trench and provided between the second gate electrode and the second face; a first field plate insulating layer provided between the first field plate electrode and the semiconductor layer; a second field plate insulating layer provided between the second field plate electrode and the semiconductor layer; a first inter-electrode insulating layer provided between the first gate electrode and the first field plate electrode; and a second inter-electrode insulating layer provided between the second gate electrode and the second field plate electrode.

Hereinafter, a case where the first conductivity type is the n type and the second conductivity type is the p type will be described as an example. That is, the case of a metal oxide semiconductor field effect transistor (MOSFET) of an n-channel type using an electron as a carrier will be described as an example.

The semiconductor device according to the first embodiment is a MOSFET 100. The MOSFET 100 is a vertical trench gate type MOSFET in which a gate electrode and a field plate electrode are provided in a trench.

The trench in the present specification is a groove-like or recess-like structure of the semiconductor layer itself, and a component other than the semiconductor layer can be provided inside the trench. The trench is a part of the semiconductor layer.

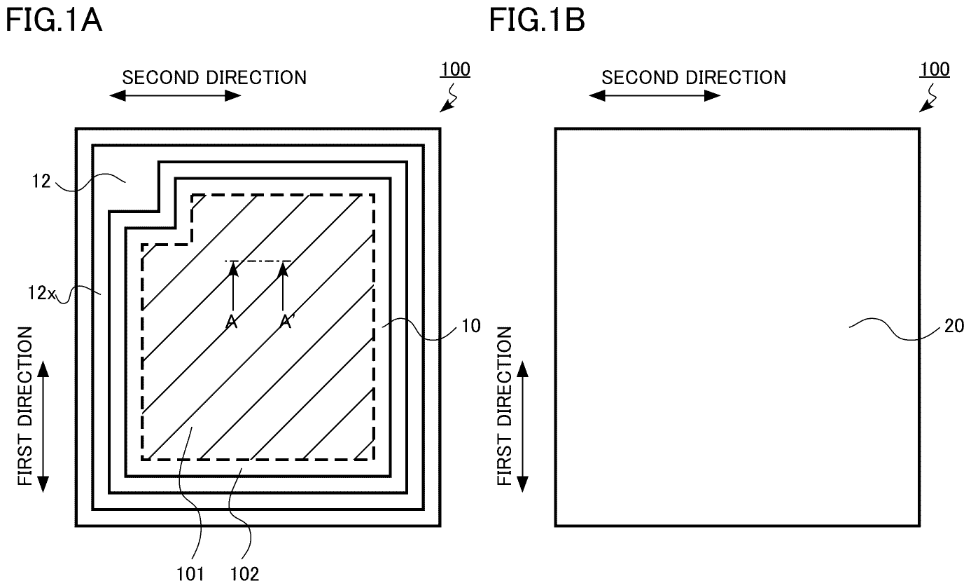

FIGS. 1A and 1B are schematic views of the semiconductor device according to the first embodiment. FIG. 1A illustrates a front surface of the MOSFET 100. FIG. 1B illustrates a back surface of the MOSFET 100.

As illustrated in FIG. 1A, a source electrode 10, a gate electrode pad 12, and a gate electrode wiring 12x are provided on a front surface side of the MOSFET 100. The gate electrode wiring 12x is connected to the gate electrode pad 12.

As illustrated in FIG. 1B, a drain electrode 20 is provided on a back surface side of the MOSFET 100.

A plurality of transistors are provided under the source electrode 10. The gate electrode pad 12 and the gate electrode wiring 12x are electrically connected to a gate electrode of the transistor. A gate voltage for controlling a switching operation of the transistor is applied to the gate electrode pad 12.

As illustrated in FIG. 1A, the MOSFET 100 includes an element region 101 and a termination region 102. The termination region 102 surrounds the element region 101. In FIG. 1A, a hatched region is the element region 101, and an outer periphery of the element region 101 is the termination region 102.

The element region 101 includes the transistor. The element region 101 includes a source region 36 of the transistor. The termination region 102 does not include the transistor. The termination region 102 does not include the source region 36.

The termination region 102 includes, for example, a termination structure for improving a breakdown voltage of the MOSFET 100. The termination structure is, for example, a RESURF structure or a guard ring structure.

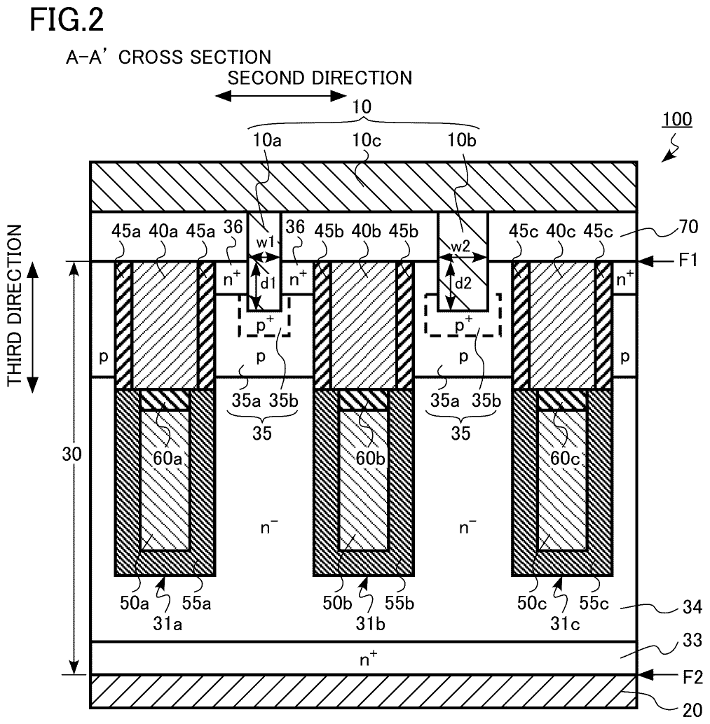

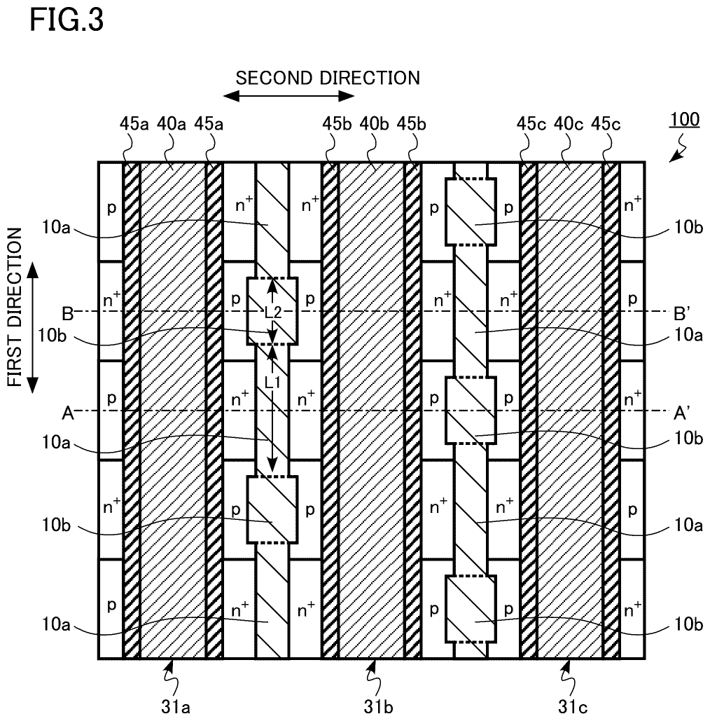

FIG. 2 is a schematic cross-sectional view of a part of the semiconductor device according to the first embodiment. FIG. 2 illustrates a cross section taken along line A-A′ in FIGS. 1A and 3.

FIG. 3 is a schematic top view of a part of the semiconductor device according to the first embodiment. FIG. 3 is a top view of a portion corresponding to FIG. 2. FIG. 3 is a view of a position corresponding to a first face F1 on a semiconductor layer 30. FIG. 3 is a view excluding components on and above the first face F1.

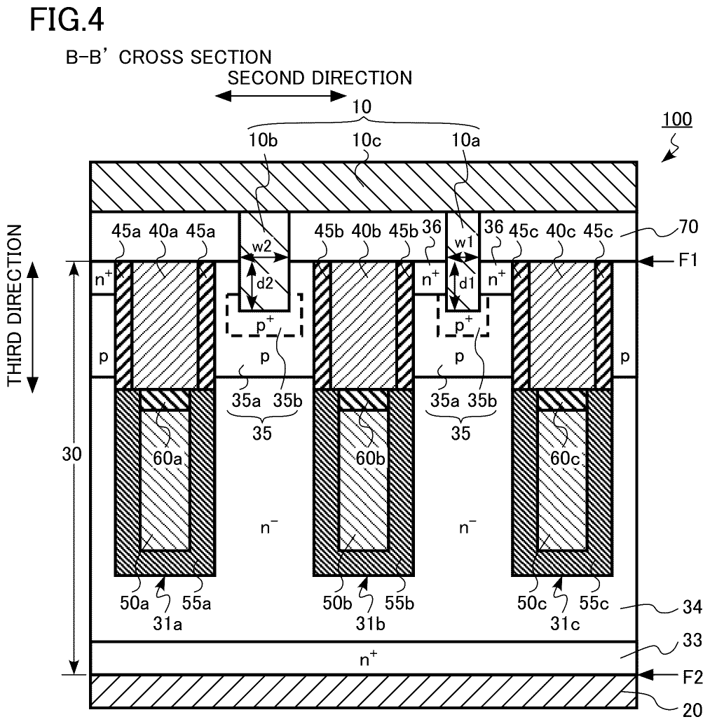

FIG. 4 is a schematic cross-sectional view of a part of the semiconductor device according to the first embodiment. FIG. 4 illustrates a cross section taken along line B-B′ in FIG. 3.

The MOSFET 100 includes the source electrode 10 (first electrode), the drain electrode 20 (second electrode), the semiconductor layer 30, a first gate electrode 40a, a second gate electrode 40b, a third gate electrode 40c, a first gate insulating layer 45a, a second gate insulating layer 45b, a third gate insulating layer 45c, a first field plate electrode 50a, a second field plate electrode 50b, a third field plate electrode 50c, a first field plate insulating layer 55a, a second field plate insulating layer 55b, a third field plate insulating layer 55c, a first inter-electrode insulating layer 60a, a second inter-electrode insulating layer 60b, a third inter-electrode insulating layer 60c, and an interlayer insulating layer 70.

Hereinafter, the first gate electrode 40a, the second gate electrode 40b, and the third gate electrode 40c may be simply referred to as a gate electrode 40 individually or collectively. In addition, the first gate insulating layer 45a, the second gate insulating layer 45b, and the third gate insulating layer 45c may be simply referred to as a gate insulating layer 45 individually or collectively. The first field plate electrode 50a, the second field plate electrode 50b, and the third field plate electrode 50c may be simply referred to as a field plate electrode 50 individually or collectively. The first field plate insulating layer 55a, the second field plate insulating layer 55b, and the third field plate insulating layer 55c may be simply referred to as a field plate insulating layer 55 individually or collectively. The first inter-electrode insulating layer 60a, the second inter-electrode insulating layer 60b, and the third inter-electrode insulating layer 60c may be simply referred to as an inter-electrode insulating layer 60 individually or collectively.

The source electrode 10 includes a first contact portion 10a (first portion), a second contact portion 10b (second portion), and a surface layer portion 10c.

The semiconductor layer 30 includes a first trench 31a, a second trench 31b, a third trench 31c, a drain region 33 of n⁺ type, a drift region 34 (first semiconductor region) of n-type, a body region 35 (second semiconductor region) of p type, and a source region 36 (third semiconductor region) of n⁺ type.

Hereinafter, the first trench 31a, the second trench 31b, and the third trench 31c may be simply referred to as a trench 31 individually or collectively.

The body region 35 includes a low-concentration region 35a (first region) and a high-concentration region 35b (second region).

The semiconductor layer 30 is provided between the source electrode 10 and the drain electrode 20. The semiconductor layer 30 has the first face (“F1” in FIG. 2) and the second face (“F2” in FIG. 2). The second face F2 faces the first face F1.

The first face F1 faces the source electrode 10. The second face F2 faces the drain electrode 20.

The first direction and the second direction are directions parallel to the first face F1. The second direction is a direction perpendicular to the first direction. A third direction is a direction perpendicular to the first face F1. The third direction is a direction perpendicular to the first direction and the second direction.

Hereinafter, the term “depth” means a depth based on the first face F1. That is, the term “depth” means a distance from the first face F1 in the third direction.

The semiconductor layer 30 is, for example, single crystal silicon (Si). In a case where the semiconductor layer 30 is single crystal silicon, a surface of the semiconductor layer 30 is, for example, a surface inclined at an angle equal to or more than 0° and equal to or less than 8° with respect to a (100) face.

The drain region 33 of n⁺ type is provided in the semiconductor layer 30. The drain region 33 is in contact with the second face F2. The drain region 33 is in contact with the drain electrode 20. The drain region 33 is electrically connected to the drain electrode 20.

The drain region 33 contains an n type impurity. The n type impurity is, for example, phosphorus (P) or arsenic (As). A concentration of the n type impurity is, for example, equal to or more than 1×10¹⁸ cm⁻³ and equal to or less than 1×10²¹ cm⁻³.

The drift region 34 of n-type is provided in the semiconductor layer 30. The drift region 34 is provided between the drain region 33 and the first face F1. The drift region 34 is provided on the drain region 33. The drift region 34 is electrically connected to the drain electrode 20. The drift region 34 functions as a current path when the MOSFET 100 is turned on.

The drift region 34 contains an n type impurity. The n type impurity is, for example, phosphorus (P) or arsenic (As). An n type impurity concentration is, for example, equal to or more than 1×10¹⁵ cm⁻³ and equal to or less than 1×10¹⁸ cm⁻³.

A thickness of the drift region 34 in the third direction is, for example, equal to or more than 5 μm and equal to or less than 15 μm.

The body region 35 of p type is provided in the semiconductor layer 30. The body region 35 is provided between the drift region 34 and the first face F1.

The body region 35 is provided between two adjacent trenches 31. The body region 35 is provided, for example, between the first trench 31a and the second trench 31b.

The body region 35 is in contact with the source electrode 10, for example. The body region 35 is electrically connected to the source electrode 10, for example.

When the MOSFET 100 is turned on, a channel of an inversion layer is formed in the body region 35 facing the gate electrode 40.

The body region 35 includes a low-concentration region 35a and a high-concentration region 35b. A p type impurity concentration of the high-concentration region 35b is higher than a p type impurity concentration of the low-concentration region 35a.

The high-concentration region 35b is provided between the low-concentration region 35a and the first face F1. The high-concentration region 35b is provided between the low-concentration region 35a and the source electrode 10.

The high-concentration region 35b is provided between the low-concentration region 35a and the first contact portion 10a. The high-concentration region 35b is provided between the low-concentration region 35a and the second contact portion 10b.

The body region 35 contains a p type impurity. The p type impurity is, for example, boron (B). A p type impurity concentration is, for example, equal to or more than 1×10¹⁶ cm⁻³ and equal to or less than 1×10²¹ cm⁻³.

The p type impurity concentration of the low-concentration region 35a is, for example, equal to or more than 1×10¹⁶ cm⁻³ and equal to or less than 1×10¹⁸ cm⁻³. The p type impurity concentration of the high-concentration region 35b is, for example, equal to or more than 1×10¹⁸ cm⁻³ and equal to or less than 1×10²¹ cm⁻³.

The source region 36 of n⁺ type is provided in the semiconductor layer 30. The source region 36 is provided between the body region 35 and the first face F1.

The source region 36 is in contact with the first face F1. The source region 36 is in contact with the source electrode 10. The source region 36 is electrically connected to the source electrode 10.

The source region 36 is provided between two adjacent trenches 31. The source region 36 is provided, for example, between the first trench 31a and the second trench 31b.

The source region 36 is provided between the first contact portion 10a and the trench 31. The source region 36 is not provided between the second contact portion 10b and the trench 31. The body region 35 is provided between the second contact portion 10b and the trench 31.

The source region 36 contains an n type impurity. The n type impurity is, for example, phosphorus (P) or arsenic (As). An n type impurity concentration is, for example, equal to or more than 1×10¹⁹ cm⁻³ and equal to or less than 1×10²¹ cm⁻³.

The trench 31 is present in the semiconductor layer 30. The trench 31 is disposed on a side of the semiconductor layer 30 facing the first face F1. The trench 31 is a groove formed in the semiconductor layer 30.

The trench 31 extends in the first direction. A plurality of trenches 31 are disposed in a repeated pattern in the second direction. The plurality of trenches 31 are disposed in a repeated pattern at a constant pitch in the second direction, for example.

The trench 31 penetrates through the body region 35 and reaches the drift region 34. A depth of the trench 31 is, for example, equal to or more than 1 μm and equal to or less than 5 μm. A width of the trench 31 in the second direction is, for example, equal to or more than 0.3 μm and equal to or less than 1 μm.

The gate electrode 40 is provided in the trench 31. The gate electrode 40 is electrically connected to the gate electrode wiring 12x and the gate electrode pad 12 by using, for example, a contact structure (not illustrated).

The gate electrode 40 is a conductor. The gate electrode 40 is, for example, polycrystalline silicon containing an n type impurity or p type impurity.

The gate insulating layer 45 is provided between the gate electrode 40 and the semiconductor layer 30. The gate insulating layer 45 is provided between the gate electrode 40 and the body region 35. The gate insulating layer 45 is provided between the gate electrode 40 and the drift region 34. The gate insulating layer 45 is provided between the gate electrode 40 and the source region 36. The gate insulating layer 45 is, for example, silicon oxide.

The field plate electrode 50 is provided in the trench 31. The field plate electrode 50 is provided between the gate electrode 40 and the second face F2 in the third direction. The field plate electrode 50 extends in the first direction.

The field plate electrode 50 has a function of changing electric field distribution in the drift region 34 and improving the breakdown voltage of the MOSFET 100 when the MOSFET 100 is turned off.

The field plate electrode 50 is electrically connected to the source electrode 10 by using, for example, the contact structure (not illustrated).

The field plate electrode 50 is a conductor. The field plate electrode 50 is, for example, polycrystalline silicon containing an n type impurity or p type impurity.

The field plate insulating layer 55 is provided between the field plate electrode 50 and the semiconductor layer 30. The field plate insulating layer 55 is provided between the field plate electrode 50 and the drift region 34. The field plate insulating layer 55 is, for example, silicon oxide.

A thickness of the field plate insulating layer 55 is larger than a thickness of the gate insulating layer 45, for example. The thickness of the field plate insulating layer 55 is, for example, 3 times or more and 30 times or less the thickness of the gate insulating layer 45.

The inter-electrode insulating layer 60 is provided between the gate electrode 40 and the field plate electrode 50. The inter-electrode insulating layer 60 is, for example, silicon oxide.

A thickness of the inter-electrode insulating layer 60 is larger than the thickness of the gate insulating layer 45, for example.

The interlayer insulating layer 70 is provided between the gate electrode 40 and the source electrode 10.

The interlayer insulating layer 70 has a function of electrically separating the gate electrode 40 and the source electrode 10. The interlayer insulating layer 70 is, for example, silicon oxide.

The source electrode 10 is provided on the side of the semiconductor layer 30 facing the first face F1. The source electrode 10 is provided on the first face F1 of the semiconductor layer 30. The source electrode 10 is electrically connected to the source region 36 and the body region 35.

The source electrode 10 includes the first contact portion 10a, the second contact portion 10b, and the surface layer portion 10c.

The first contact portion 10a is provided between the semiconductor layer 30 and the surface layer portion 10c. The first contact portion 10a is provided between two gate electrodes 40 adjacent to each other in the second direction. The first contact portion 10a is provided, for example, between the first gate electrode 40a and the second gate electrode 40b. The first contact portion 10a is provided, for example, between the second gate electrode 40b and the third gate electrode 40c.

The first contact portion 10a is in contact with the semiconductor layer 30. The first contact portion 10a is in contact with the body region 35. For example, a bottom face and side faces of the first contact portion 10a are in contact with the body region 35. For example, the first contact portion 10a is in contact with the high-concentration region 35b of the body region 35. For example, the bottom face and the side faces of the first contact portion 10a are in contact with the high-concentration region 35b of the body region 35.

The first contact portion 10a is in contact with the source region 36. For example, the side faces of the first contact portion 10a are in contact with the source region 36.

A part of the first contact portion 10a fills a recess provided in the semiconductor layer 30. A part of the first contact portion 10a is provided in the recess provided in the semiconductor layer 30. The recess extends in the first direction.

The first contact portion 10a is sandwiched between a part and another part of the semiconductor layer 30 in the second direction. For example, the first contact portion 10a is sandwiched between the source region 36 and the source region 36 in the second direction.

A width of the first contact portion 10a in the second direction is a first width (w1 in FIG. 2). The first width w1 of the first contact portion 10a in the second direction is, for example, a width in the second direction at a position corresponding to the first face F1 on the first contact portion 10a.

A depth of the first contact portion 10a in the third direction is a first depth (d1 in FIG. 2). The depth of the first contact portion 10a in the third direction is a depth from the first face F1.

A length of the first contact portion 10a in the first direction is a first length (L1 in FIG. 3). The first length L1 of the first contact portion 10a in the first direction is, for example, a length in the first direction at the position corresponding to the first face F1 on the first contact portion 10a.

The first depth d1 of the first contact portion 10a is larger than a depth of the source region 36, for example.

The second contact portion 10b is provided between the semiconductor layer 30 and the surface layer portion 10c. The second contact portion 10b is provided between two gate electrodes 40 adjacent to each other in the second direction. The second contact portion 10b is provided, for example, between the first gate electrode 40a and the second gate electrode 40b. The second contact portion 10b is provided, for example, between the second gate electrode 40b and the third gate electrode 40c.

The second contact portion 10b is provided in the first direction with respect to the first contact portion 10a.

The second contact portion 10b is in contact with the semiconductor layer 30. The second contact portion 10b is in contact with the body region 35. For example, a bottom face and side faces of the second contact portion 10b are in contact with the body region 35. For example, the second contact portion 10b is in contact with the high-concentration region 35b of the body region 35. For example, the bottom face and the side faces of the second contact portion 10b are in contact with the high-concentration region 35b of the body region 35.

The second contact portion 10b is not in contact with the source region 36. The source region 36 is not provided around the second contact portion 10b.

A part of the second contact portion 10b fills a recess provided in the semiconductor layer 30. A part of the second contact portion 10b is provided in the recess provided in the semiconductor layer 30. The recess extends in the first direction. A part of the second contact portion 10b is provided in the same recess as a part of the first contact portion 10a.

The second contact portion 10b is sandwiched between a part and another part of the semiconductor layer 30 in the second direction. For example, the second contact portion 10b is sandwiched between the body region 35 and the body region 35 in the second direction.

A width of the second contact portion 10b in the second direction is a second width (w2 in FIG. 2). The second width w2 of the second contact portion 10b in the second direction is, for example, a width in the second direction at a position corresponding to the first face F1 on the second contact portion 10b.

The second width w2 of the second contact portion 10b is larger than the first width w1 of the first contact portion 10a. The second width w2 is, for example, 1.2 times or more and 3 times or less the first width w1.

A depth of the second contact portion 10b in the third direction is a second depth (d2 in FIG. 2). The depth of the second contact portion 10b in the third direction is a depth from the first face F1.

The second depth d2 of the second contact portion 10b is larger than the depth of the source region 36, for example.

The second depth d2 of the second contact portion 10b is, for example, substantially the same as the first depth d1 of the first contact portion 10a.

A length of the second contact portion 10b in the first direction is a second length (L2 in FIG. 3). The second length L2 of the second contact portion 10b in the first direction is, for example, a length in the first direction at a position corresponding to the first face F1 on the second contact portion 10b.

The first length L1 of the first contact portion 10a is larger than the second length L2 of the second contact portion 10b, for example. The first length L1 of the first contact portion 10a is, for example, 2 times or more and 10 times or less the second length L2 of the second contact portion 10b.

For example, as illustrated in FIG. 3, a plurality of first contact portions 10a and a plurality of second contact portions 10b are alternately provided in a repeated pattern in the first direction between two gate electrodes 40 adjacent to each other in the second direction. The width of the contact portion including the first contact portion 10a and the second contact portion 10b in the second direction repeatedly increases and decreases in the first direction.

For example, as illustrated in FIG. 3, the repeated pattern of the first contact portion 10a and the second contact portion 10b is shifted in the first direction between the first gate electrode 40a and the second gate electrode 40b and between the second gate electrode 40b and the third gate electrode 40c. The first contact portion 10a between the second gate electrode 40b and the third gate electrode 40c is provided in the second direction with respect to the second contact portion 10b between the first gate electrode 40a and the second gate electrode 40b.

The surface layer portion 10c is provided on the plurality of first contact portions 10a and the plurality of second contact portions 10b. The surface layer portion 10c electrically connects the plurality of first contact portions 10a and the plurality of second contact portions 10b.

The surface layer portion 10c is a region to which a bonding wire is connected, for example, when the MOSFET 100 is mounted.

The source electrode 10 is a conductor. The source electrode 10 is, for example, metal. The first contact portion 10a, the second contact portion 10b, and the surface layer portion 10c may be formed of the same material or different materials.

The first contact portion 10a and the second contact portion 10b have, for example, a stacked structure of titanium, titanium nitride, and tungsten. The surface layer portion 10c has, for example, a stacked structure of titanium nitride and aluminum.

The drain electrode 20 is provided on a side of the semiconductor layer 30 facing the second face F2. The drain electrode 20 is provided on the second face F2 of the semiconductor layer 30. The drain electrode 20 is electrically connected to the drain region 33. The drain electrode 20 is in contact with the drain region 33. The drain electrode 20 is electrically connected to the drift region 34.

The drain electrode 20 is metal. The drain electrode 20 has, for example, a stacked structure of materials selected from titanium, aluminum, nickel, copper, silver, and gold.

The gate electrode pad 12 is provided on the side of the semiconductor layer 30 facing the first face F1. The gate electrode pad 12 is provided on the first face F1 of the semiconductor layer 30. As illustrated in FIG. 1A, for example, the gate electrode pad 12 and the gate electrode wiring 12x surround the source electrode 10.

The gate electrode pad 12 is electrically connected to the gate electrode 40. The gate electrode pad 12 is, for example, a region to which a bonding wire is connected when the MOSFET 100 is mounted.

The gate electrode pad 12 is metal. The gate electrode pad 12 has, for example, a stacked structure of titanium nitride and aluminum. A material of the gate electrode pad 12 is, for example, the same as a material of the source electrode 10.

The gate electrode wiring 12x is electrically connected to the gate electrode 40. The gate electrode pad 12 and the gate electrode 40 are electrically connected by using the gate electrode wiring 12x.

The gate electrode wiring 12x is metal. The gate electrode wiring 12x has, for example, a stacked structure of titanium nitride and aluminum. A material of the gate electrode wiring 12x is, for example, the same as the material of the source electrode 10 and the material of the gate electrode pad 12.

The MOSFET 100 according to the first embodiment can be manufactured, for example, by performing patterning such that a width of an opening corresponding to the second contact portion 10b is larger than a width of an opening corresponding to the first contact portion 10a when forming the openings for providing the first contact portion 10a and the second contact portion 10b in the interlayer insulating layer 70.

Next, functions and effects of the semiconductor device according to the first embodiment will be described.

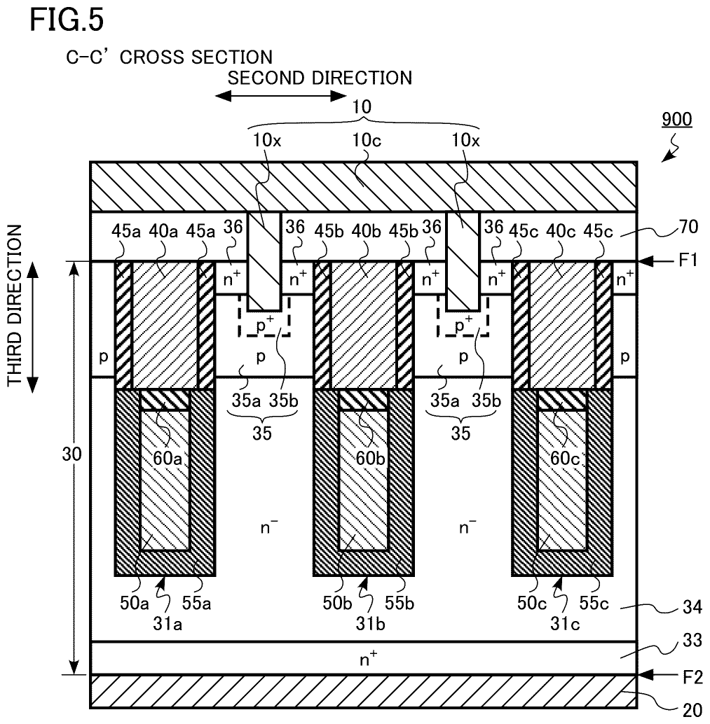

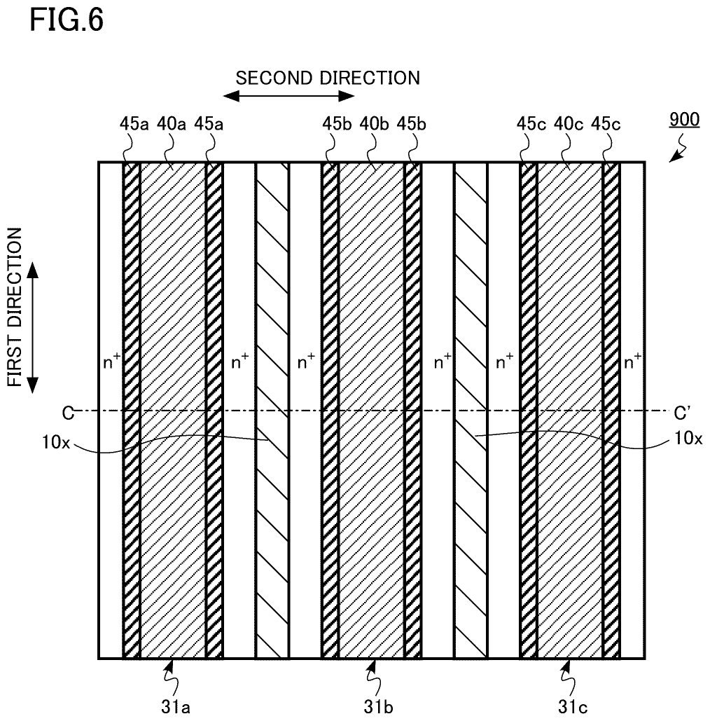

FIG. 5 is a schematic cross-sectional view of a part of a semiconductor device according to a comparative embodiment. FIG. 5 illustrates a cross section taken along line C-C′ in FIG. 6. FIG. 5 is a view corresponding to FIG. 2 of the first embodiment.

FIG. 6 is a schematic top view of a part of the semiconductor device according to the comparative embodiment. FIG. 5 is a view corresponding to FIG. 3 of the first embodiment.

The semiconductor device according to the comparative embodiment is a MOSFET 900. The MOSFET 900 is different from the MOSFET 100 according to the first embodiment in that a width of a contact portion of a source electrode is constant.

A source electrode 10 of the MOSFET 900 includes a contact portion 10x. The contact portion 10x has the same structure as the first contact portion 10a of the MOSFET 100 according to the first embodiment. In the MOSFET 900, the contact portion 10x is continuously provided in a first direction between two gate electrodes 40 adjacent to each other in a second direction.

In the MOSFET 900, for example, avalanche capability may decrease. For example, when avalanche breakdown occurs during a turn-off operation of the MOSFET 900, holes are discharged from the contact portion 10x to the source electrode 10 in a body region 35. In a case where the discharge of the holes from the contact portion 10x is insufficient, a parasitic NPN transistor is turned on, and a large current flows to destroy the MOSFET 900. When the discharge of the holes from the contact portion 10x is insufficient, the parasitic NPN transistor is turned on early, and the avalanche capability of the MOSFET 900 decreases.

In order to promote the discharge of the holes from the contact portion 10x, for example, it is conceivable to increase a width of the contact portion 10x in the second direction. As the width of the contact portion 10x in the second direction is increased, the discharge of the holes from the contact portion 10x is promoted, and the parasitic NPN transistor is less likely to be turned on.

However, for example, when the width of the contact portion 10x is increased, a threshold voltage of the transistor may increase due to an influence of a high-concentration region 35b of p type provided on side faces and a bottom face of the contact portion 10x. When the threshold voltage of the transistor increases, an on-current of the MOSFET 900 decreases, which is not preferable.

In the MOSFET 100 according to the first embodiment, the second width w2 of the second contact portion 10b is larger than the first width w1 of the first contact portion 10a. Discharge of holes from the second contact portion 10b is promoted by increasing the second width w2 of the second contact portion 10b. Therefore, avalanche capability of the MOSFET 100 is improved.

Further, in the MOSFET 100, the second contact portion 10b is not in contact with the source region 36. The source region 36 is not provided around the second contact portion 10b. Therefore, a contact area between the second contact portion 10b and the body region 35 increases as compared with a case where the second contact portion 10b is in contact with the source region 36. Therefore, the avalanche capability of the MOSFET 100 is further improved.

In addition, since the second contact portion 10b is not in contact with the source region 36, a region under the second contact portion 10b does not operate as the transistor. Therefore, parasitic formation of a transistor having a high threshold voltage under the second contact portion 10b is suppressed. Therefore, for example, variation in on-current of the MOSFET 100 is suppressed.

In the MOSFET 100 according to the first embodiment, the first width w1 of the first contact portion 10a is smaller than the second width w2 of the second contact portion 10b. Therefore, an increase in threshold voltage of the transistor due to the influence of the high-concentration region 35b of p type provided on the side faces and the bottom face of the contact portion 10x is suppressed. Therefore, a decrease in on-current of the MOSFET 100 is suppressed.

Further, the MOSFET 100 according to the first embodiment includes the field plate electrode 50. Since the avalanche capability is improved by the second contact portion 10b, the n type impurity concentration of the drift region 34 between the trenches 31 can be increased. Therefore, as the second contact portion 10b is provided, an electric resistance of the drift region 34 is reduced, and the on-current of the MOSFET 100 can be increased.

With the MOSFET 100 according to the first embodiment, it is possible to implement a MOSFET with improved avalanche capability.

From the viewpoint of improving the avalanche capability of the MOSFET 100, the second width w2 of the second contact portion 10b is preferably 1.2 times or more, and more preferably 1.5 times or more the first width w1 of the first contact portion 10a.

From the viewpoint of suppressing a decrease in on-current of the MOSFET 100, the first length L1 of the first contact portion 10a is preferably larger than the second length L2 of the second contact portion 10b. In addition, from the viewpoint of suppressing a decrease in on-current of the MOSFET 100, the first length L1 of the first contact portion 10a is more preferably 2 times or more, and still more preferably 5 times or more the second length L2 of the second contact portion 10b.

### First Modified Example

A semiconductor device according to a first modified example of the first embodiment is different from the semiconductor device according to the first embodiment in that a second portion is in contact with a third semiconductor region.

The semiconductor device according to the first modified example of the first embodiment is a MOSFET 110. The MOSFET 110 is a vertical trench gate type MOSFET in which a gate electrode and a field plate electrode are provided in a trench.

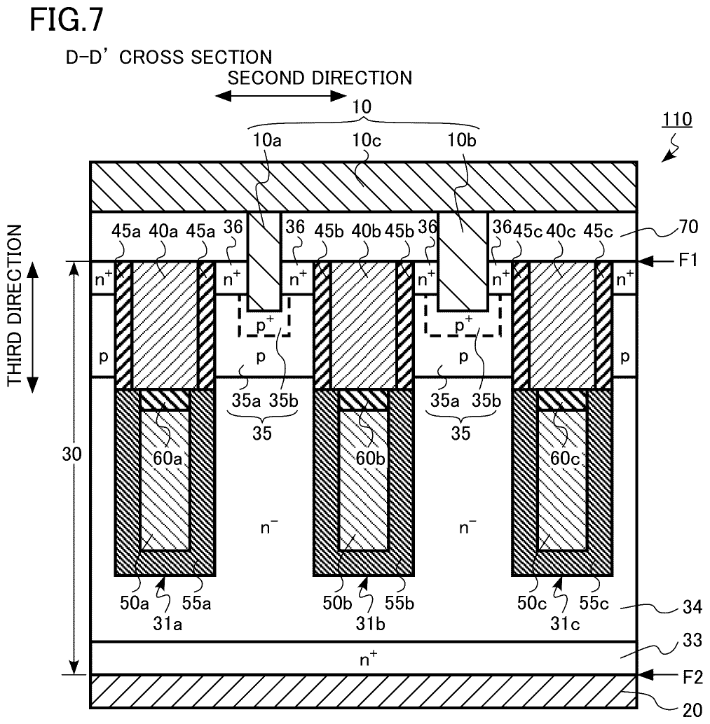

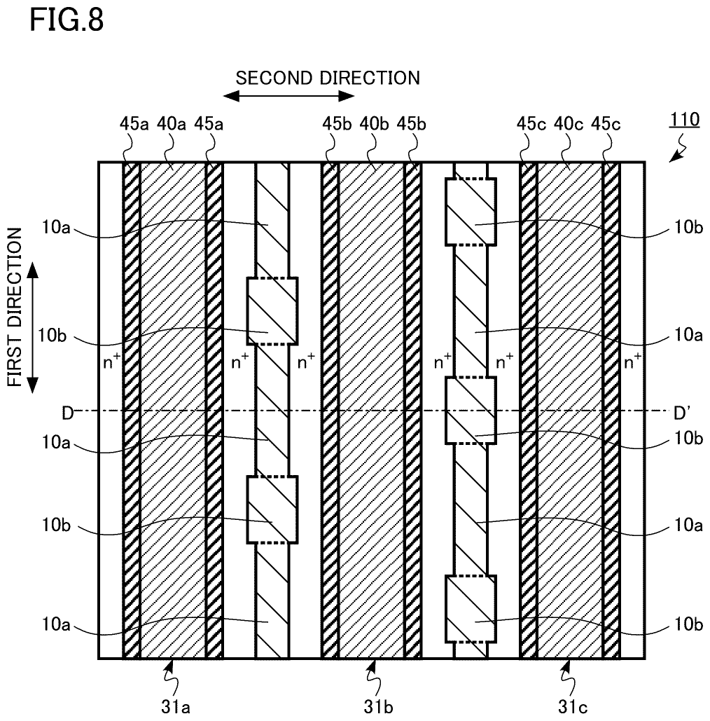

FIG. 7 is a schematic cross-sectional view of a part of the semiconductor device according to the first modified example of the first embodiment. FIG. 7 illustrates a cross section taken along line D-D′ in FIG. 8. FIG. 7 is a view corresponding to FIG. 2 of the first embodiment.

FIG. 8 is a schematic top view of a part of the semiconductor device according to the first modified example of the first embodiment. FIG. 8 is a view corresponding to FIG. 3 of the first embodiment.

In the MOSFET 110 according to the first modified example of the first embodiment, a second contact portion 10b is in contact with a source region 36. In the MOSFET 110, the source region 36 is provided in a semiconductor layer 30 around the second contact portion 10b.

With the MOSFET 110 according to the first modified example of the first embodiment, similarly to the MOSFET 100 according to the first embodiment, it is possible to implement a MOSFET with improved avalanche capability.

### Second Modified Example

A semiconductor device according to a second modified example of the first embodiment is different from the semiconductor device according to the first embodiment in that a repeated pattern of a first contact portion and a second contact portion is not shifted in a first direction between a first gate electrode and a second gate electrode and between a second gate electrode and a third gate electrode.

The semiconductor device according to the second modified example of the first embodiment is a MOSFET 120. The MOSFET 120 is a vertical trench gate type MOSFET in which a gate electrode and a field plate electrode are provided in a trench.

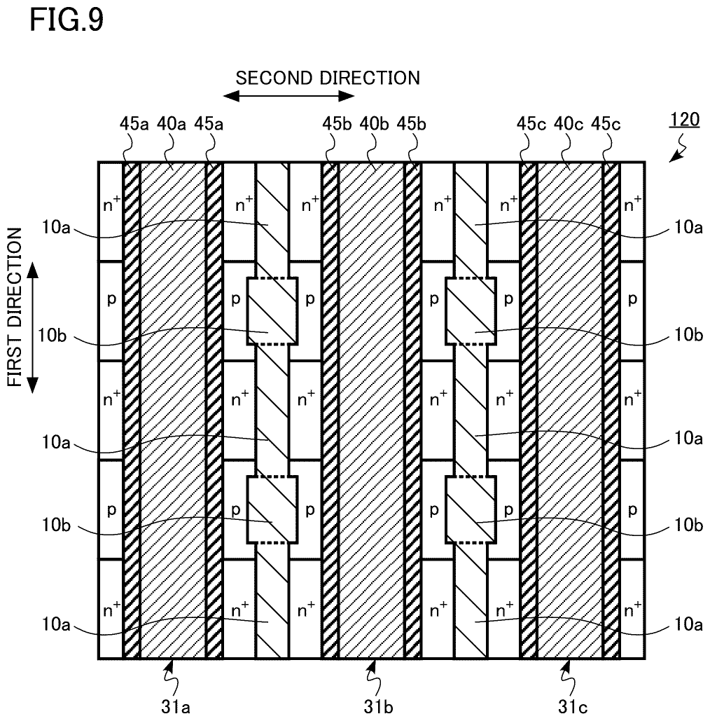

FIG. 9 is a schematic top view of a part of the semiconductor device according to the second modified example of the first embodiment. FIG. 9 is a view corresponding to FIG. 3 of the first embodiment.

A repeated pattern of a first contact portion 10a and a second contact portion 10b is not shifted in the first direction between a first gate electrode 40a and a second gate electrode 40b and between a second gate electrode 40b and a third gate electrode 40c. The first contact portion 10a is provided in a second direction with respect to the first contact portion 10a. The second contact portion 10b is provided in the second direction with respect to the second contact portion 10b.

With the MOSFET 120 according to the second modified example of the first embodiment, similarly to the MOSFET 100 according to the first embodiment, it is possible to implement a MOSFET with improved avalanche capability.

### Third Modified Example

A semiconductor device according to a third modified example of the first embodiment is different from the semiconductor device according to the first embodiment in that a field plate electrode is not provided.

The semiconductor device according to the third modified example of the first embodiment is a MOSFET 130. The MOSFET 130 is a vertical trench gate type MOSFET in which a gate electrode is provided in a trench.

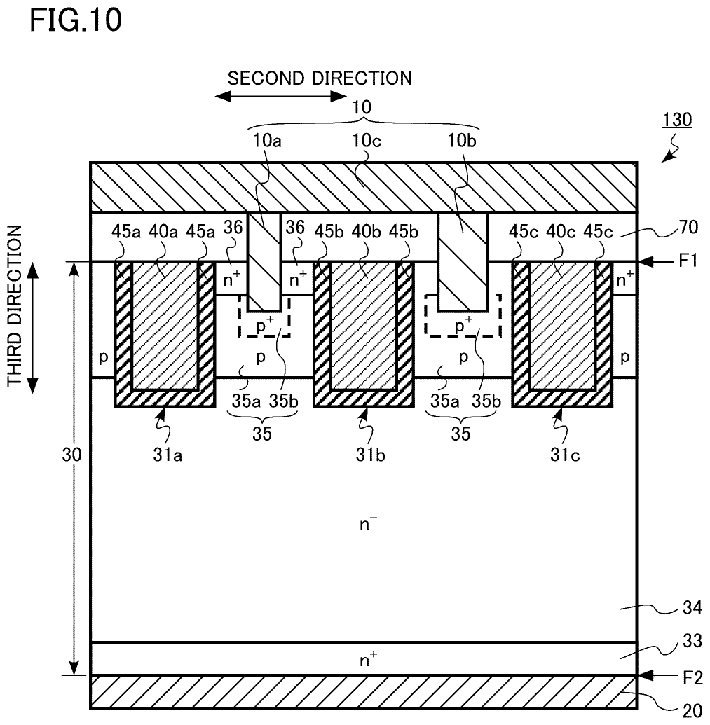

FIG. 10 is a schematic cross-sectional view of a part of the semiconductor device according to the third modified example of the first embodiment. FIG. 10 is a view corresponding to FIG. 2 of the first embodiment.

The MOSFET 130 according to the third modified example of the first embodiment does not include a field plate electrode 50.

With the MOSFET 130 according to the third modified example of the first embodiment, similarly to the MOSFET 100 according to the first embodiment, it is possible to implement a MOSFET with improved avalanche capability.

### Fourth Modified Example

A semiconductor device according to a fourth modified example of the first embodiment is different from the semiconductor device according to the first embodiment in that a trench is not provided.

The semiconductor device according to the fourth modified example of the first embodiment is a MOSFET 140. The MOSFET 140 is a vertical planar gate type MOSFET in which a gate electrode is provided on a surface of a semiconductor layer.

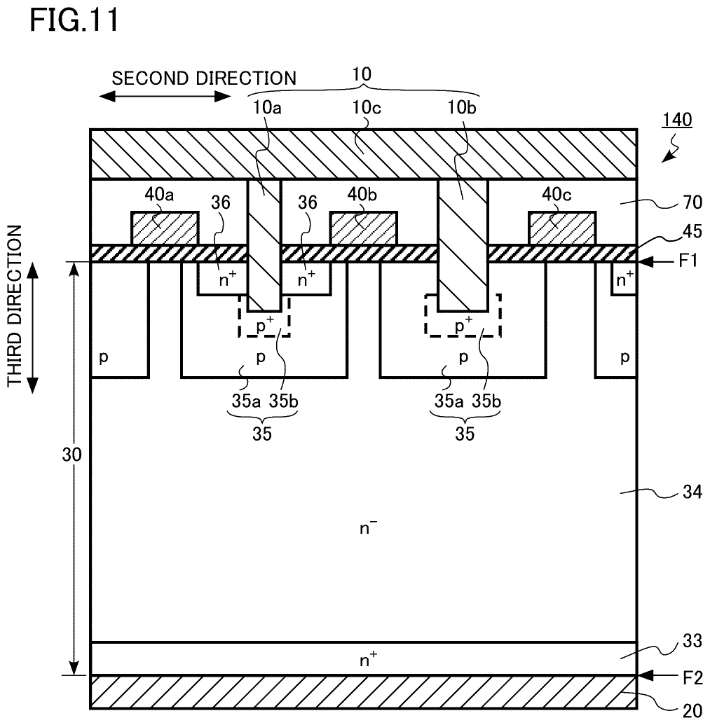

FIG. 11 is a schematic cross-sectional view of a part of the semiconductor device according to the fourth modified example of the first embodiment. FIG. 11 is a view corresponding to FIG. 2 of the first embodiment.

The MOSFET 140 according to the fourth modified example of the first embodiment does not include a trench 31. The MOSFET 140 according to the fourth modified example is a planar gate type MOSFET.

With the MOSFET 140 according to the fourth modified example of the first embodiment, similarly to the MOSFET 100 according to the first embodiment, it is possible to implement a MOSFET with improved avalanche capability.

### Fifth Modified Example

A semiconductor device according to a fifth modified example of the first embodiment is different from the semiconductor device according to the first embodiment in that a gate electrode is divided into two parts in a second direction.

The semiconductor device according to the fifth modified example of the first embodiment is a MOSFET 150. The MOSFET 150 is a vertical trench gate type MOSFET in which a gate electrode and a field plate electrode are provided in a trench.

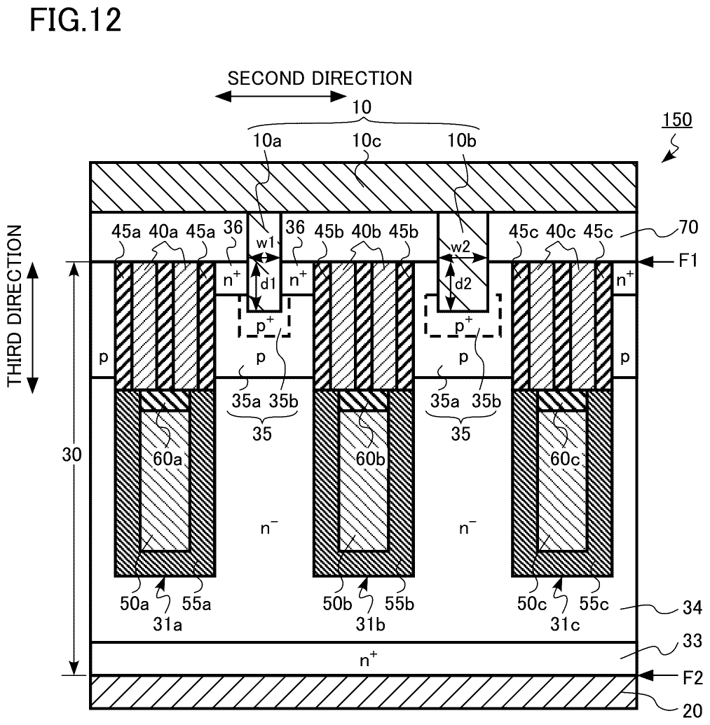

FIG. 12 is a schematic cross-sectional view of a part of the semiconductor device according to the fifth modified example of the first embodiment. FIG. 12 is a view corresponding to FIG. 2 of the first embodiment.

In the MOSFET 150 according to the fifth modified example of the first embodiment, a gate electrode 40 is divided into two parts in the second direction.

With the MOSFET 150 of the fifth modified example of the first embodiment, similarly to the MOSFET 100 according to the first embodiment, it is possible to implement a MOSFET with improved avalanche capability.

As described above, according to the first embodiment and the modified examples, it is possible to implement a semiconductor device with improved avalanche capability.

### Second Embodiment

A semiconductor device according to a second embodiment is different from the semiconductor device according to the first embodiment in that a second depth of a second portion is larger than a first depth of a first portion. Hereinafter, a description of contents overlapping the first embodiment may be partially omitted.

The semiconductor device according to the second embodiment is a MOSFET 200. The MOSFET 200 is a vertical trench gate type MOSFET in which a gate electrode and a field plate electrode are provided in a trench.

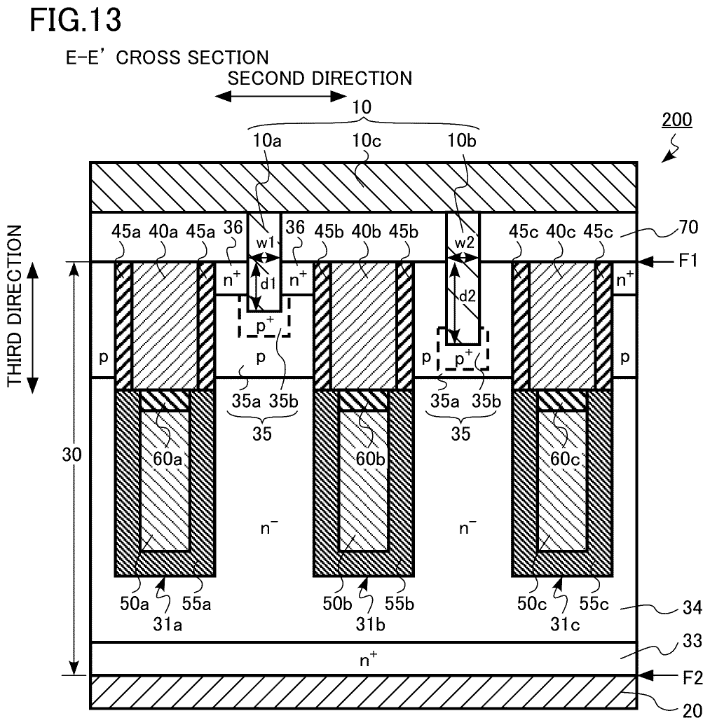

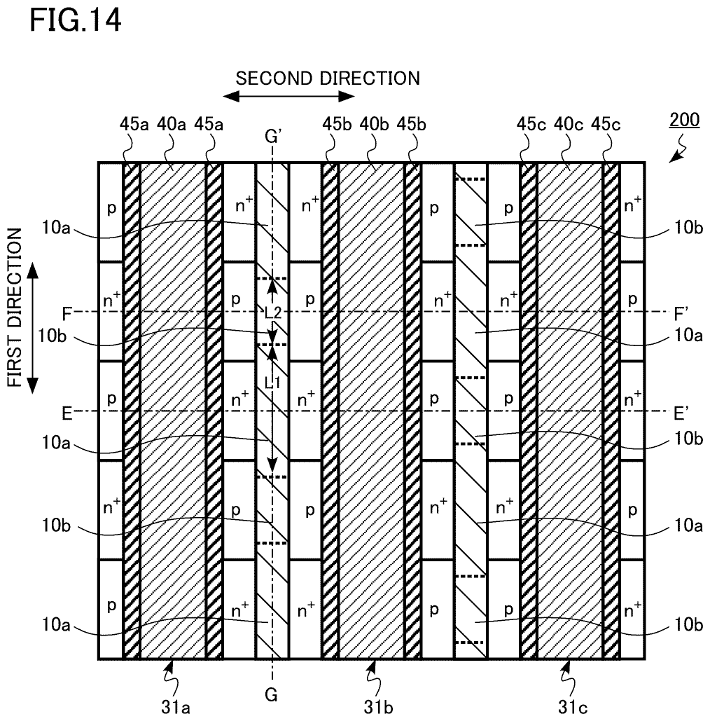

FIG. 13 is a schematic cross-sectional view of a part of the semiconductor device according to the second embodiment. FIG. 13 illustrates a cross section taken along line E-E′ in FIG. 14.

FIG. 14 is a schematic top view of a part of the semiconductor device according to the second embodiment. FIG. 14 is a top view of a portion corresponding to FIG. 13. FIG. 14 is a view of a position corresponding to a first face F1 on a semiconductor layer 30. FIG. 14 is a view excluding components on and above the first face F1.

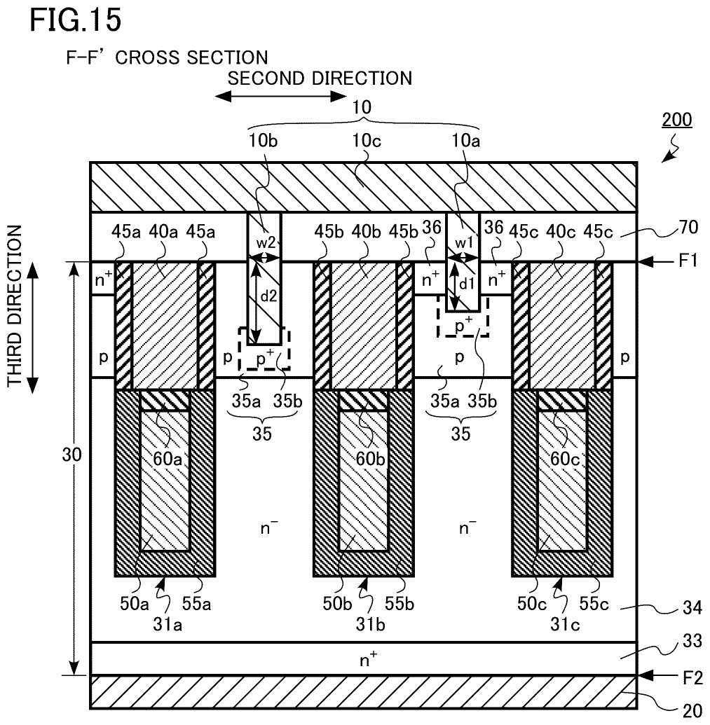

FIG. 15 is a schematic cross-sectional view of a part of the semiconductor device according to the second embodiment. FIG. 15 illustrates a cross section taken along line F-F′ in FIG. 14.

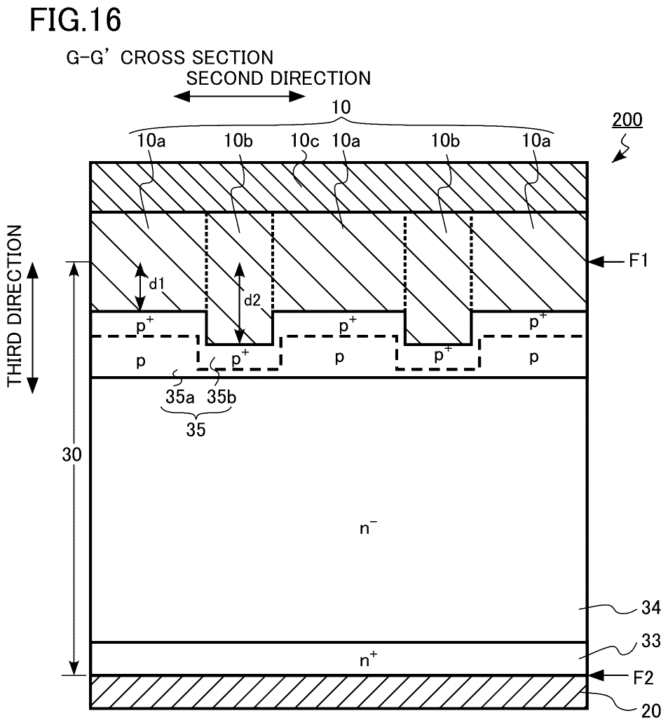

FIG. 16 is a schematic cross-sectional view of a part of the semiconductor device according to the second embodiment. FIG. 16 illustrates a cross section taken along line G-G′ in FIG. 14.

A first contact portion 10a is in contact with a source region 36. For example, side faces of the first contact portion 10a are in contact with the source region 36.

A width of the first contact portion 10a in a second direction is a first width (w1 in FIG. 13). The first width w1 of the first contact portion 10a in the second direction is, for example, a width in the second direction at a position corresponding to the first face F1 on the first contact portion 10a.

A depth of the first contact portion 10a in a third direction is a first depth (d1 in FIG. 13). The depth of the first contact portion 10a in the third direction is a depth from the first face F1.

A length of the first contact portion 10a in the first direction is a first length (L1 in FIG. 14). The first length L1 of the first contact portion 10a in the first direction is, for example, a length in the first direction at the position corresponding to the first face F1 on the first contact portion 10a.

The first depth d1 of the first contact portion 10a is larger than a depth of the source region 36, for example.

A second contact portion 10b is not in contact with the source region 36. The source region 36 is not provided around the second contact portion 10b.

A width of the second contact portion 10b in the second direction is a second width (w2 in FIG. 13). The second width w2 of the second contact portion 10b in the second direction is, for example, a width in the second direction at a position corresponding to the first face F1 on the second contact portion 10b.

The second width w2 of the second contact portion 10b is, for example, substantially the same as the first width w1 of the first contact portion 10a.

A depth of the second contact portion 10b in the third direction is a second depth (d2 in FIG. 13). The depth of the second contact portion 10b in the third direction is a depth from the first face F1.

The second depth d2 of the second contact portion 10b is larger than the depth of the source region 36, for example.

The second depth d2 of the second contact portion 10b is larger than the first depth d1 of the first contact portion 10a. The second depth d2 of the second contact portion 10b is, for example, 1.2 times or more and 2 times or less the first depth d1 of the first contact portion 10a.

A length of the second contact portion 10b in the first direction is a second length (L2 in FIG. 14). The second length L2 of the second contact portion 10b in the first direction is, for example, a length in the first direction at a position corresponding to the first face F1 on the second contact portion 10b.

The first length L1 of the first contact portion 10a is larger than the second length L2 of the second contact portion 10b, for example. The first length L1 of the first contact portion 10a is, for example, 2 times or more and 10 times or less the second length L2 of the second contact portion 10b.

For example, as illustrated in FIG. 14, a plurality of first contact portions 10a and a plurality of second contact portions 10b are alternately provided in a repeated pattern in the first direction between two gate electrodes 40 adjacent to each other in the second direction. As illustrated in FIG. 16, the depth of the contact portion including the first contact portion 10a and the second contact portion 10b in the third direction repeatedly increases and decreases in the first direction.

For example, as illustrated in FIG. 14, the repeated pattern of the first contact portion 10a and the second contact portion 10b is shifted in the first direction between a first gate electrode 40a and a second gate electrode 40b and between the second gate electrode 40b and a third gate electrode 40c. The first contact portion 10a between the second gate electrode 40b and the third gate electrode 40c is provided in the second direction with respect to the second contact portion 10b between the first gate electrode 40a and the second gate electrode 40b.

The MOSFET 200 according to the second embodiment can be manufactured by, for example, performing patterning such that a depth of a recess corresponding to the second contact portion 10b is larger than a depth of a recess corresponding to the first contact portion 10a when forming the recesses for providing the first contact portion 10a and the second contact portion 10b in the semiconductor layer 30 by performing etching twice.

Next, functions and effects of the semiconductor device according to the second embodiment will be described.

In the MOSFET 900 according to the comparative embodiment described with reference to FIGS. 5 and 6 for the first embodiment, for example, it is conceivable to increase the depth of the contact portion 10x in the third direction in order to promote the discharge of the holes from the contact portion 10x. As the depth of the contact portion 10x in the third direction is increased, the discharge of the holes from the contact portion 10x is promoted, and the parasitic NPN transistor is less likely to be turned on.

However, for example, when the depth of the contact portion 10x is increased, the threshold voltage of the transistor may increase due to the influence of the high-concentration region 35b of p type provided on the side faces and the bottom face of the contact portion 10x. When the threshold voltage of the transistor increases, the on-current of the MOSFET 900 decreases, which is not preferable.

In the MOSFET 200 according to the second embodiment, the second depth d2 of the second contact portion 10b is larger than the first depth d1 of the first contact portion 10a. Discharge of holes from the second contact portion 10b is promoted by increasing the second depth d2 of the second contact portion 10b. Therefore, avalanche capability of the MOSFET 200 is improved.

Further, in the MOSFET 200, the second contact portion 10b is not in contact with the source region 36. The source region 36 is not provided around the second contact portion 10b. Therefore, a contact area between the second contact portion 10b and a body region 35 increases as compared with a case where the second contact portion 10b is in contact with the source region 36. Therefore, the avalanche capability of the MOSFET 200 is further improved.

In addition, since the second contact portion 10b is not in contact with the source region 36, a region under the second contact portion 10b does not operate as the transistor. Therefore, parasitic formation of a transistor having a high threshold voltage under the second contact portion 10b is suppressed. Therefore, for example, variation in on-current of the MOSFET 200 is suppressed.

In the MOSFET 200 according to the second embodiment, the first depth d1 of the first contact portion 10a is smaller than the second depth d2 of the second contact portion 10b. Therefore, an increase in threshold voltage of the transistor due to the influence of the high-concentration region 35b of p type provided on the side faces and the bottom face of the contact portion 10x is suppressed. Therefore, a decrease in on-current of the MOSFET 200 is suppressed.

Further, the MOSFET 200 according to the second embodiment includes a field plate electrode 50. Since the avalanche capability is improved by the second contact portion 10b, an n type impurity concentration of a drift region 34 between trenches 31 can be increased. Therefore, as the second contact portion 10b is provided, an electric resistance of the drift region 34 can be reduced, and the on-current of the MOSFET 200 can be increased.

With the MOSFET 200 according to the second embodiment, it is possible to implement a MOSFET with improved avalanche capability.

From the viewpoint of improving the avalanche capability of the MOSFET 200, the second depth d2 of the second contact portion 10b is preferably 1.2 times or more, and more preferably 1.5 times or more the first depth d1 of the first contact portion 10a.

From the viewpoint of suppressing a decrease in on-current of the MOSFET 200, the first length L1 of the first contact portion 10a is preferably larger than the second length L2 of the second contact portion 10b. In addition, from the viewpoint of suppressing a decrease in on-current of the MOSFET 200, the first length L1 of the first contact portion 10a is more preferably 2 times or more, and still more preferably 5 times or more the second length L2 of the second contact portion 10b.

### First Modified Example

A semiconductor device according to a first modified example of the second embodiment is different from the semiconductor device according to the second embodiment in that a second portion is in contact with a third semiconductor region.

The semiconductor device according to the first modified example of the second embodiment is a MOSFET 210. The MOSFET 210 is a vertical trench gate type MOSFET in which a gate electrode and a field plate electrode are provided in a trench.

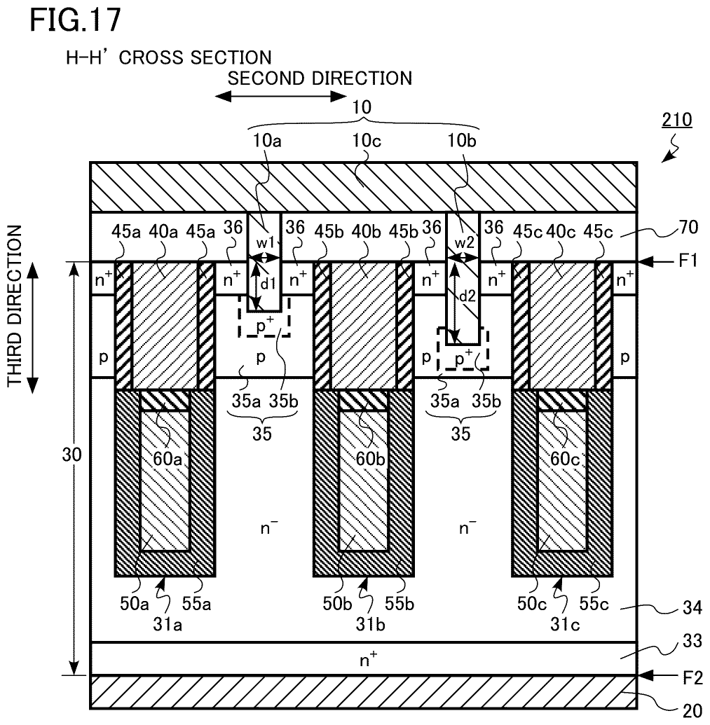

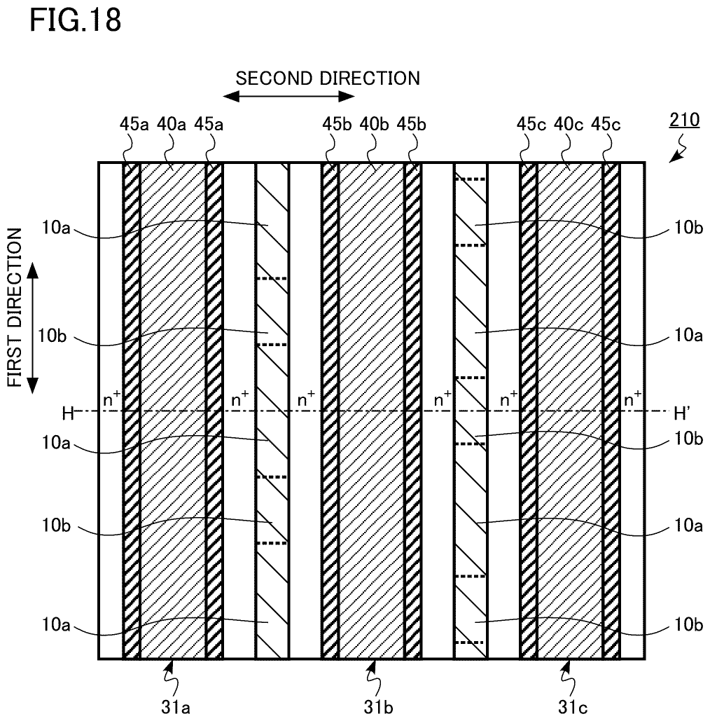

FIG. 17 is a schematic cross-sectional view of a part of the semiconductor device according to the first modified example of the second embodiment. FIG. 17 illustrates a cross section taken along line H-H′ in FIG. 18. FIG. 17 is a view corresponding to FIG. 13 of the second embodiment.

FIG. 18 is a schematic top view of a part of the semiconductor device according to the first modified example of the second embodiment. FIG. 18 is a view corresponding to FIG. 14 of the second embodiment.

In the MOSFET 210 according to the first modified example of the second embodiment, a second contact portion 10b is in contact with a source region 36. In the MOSFET 210, the source region 36 is provided in a semiconductor layer 30 around the second contact portion 10b.

With the MOSFET 210 according to the first modified example of the second embodiment, similarly to the MOSFET 200 according to the second embodiment, it is possible to implement a MOSFET with improved avalanche capability.

### Second Modified Example

A semiconductor device according to a second modified example of the second embodiment is different from the semiconductor device according to the second embodiment in that a second depth of a second portion is larger than a first depth of a first portion, and a second width of the second portion in a second direction is larger than a first width of the first portion in the second direction.

The semiconductor device according to the second modified example of the second embodiment is a MOSFET 220. The MOSFET 220 is a vertical trench gate type MOSFET in which a gate electrode and a field plate electrode are provided in a trench.

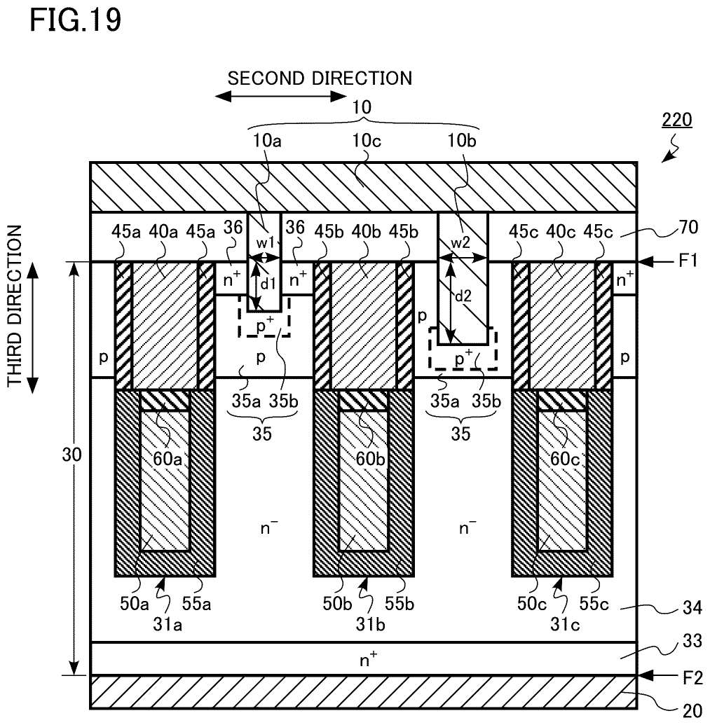

FIG. 19 is a schematic cross-sectional view of a part of the semiconductor device according to the second modified example of the second embodiment. FIG. 19 is a view corresponding to FIG. 13 of the second embodiment.

In the MOSFET 220 according to the second modified example of the second embodiment, a second width w2 of a second contact portion 10b is larger than a first width w1 of a first contact portion 10a. The second width w2 is, for example, 1.2 times or more and 3 times or less the first width w1.

In the MOSFET 220 according to the second modified example of the second embodiment, discharge of holes from the second contact portion 10b is further promoted.

With the MOSFET 220 according to the second modified example of the second embodiment, similarly to the MOSFET 200 according to the second embodiment, it is possible to implement a MOSFET with improved avalanche capability.

As a modified example of the second embodiment, for example, as in the second modified example of the first embodiment, it is also possible to adopt a form in which a repeated pattern of the first contact portion and the second contact portion is not shifted in a first direction between a first gate electrode and a second gate electrode and between the second gate electrode and a third gate electrode.

Further, as a modified example of the second embodiment, for example, as in the third modified example of the first embodiment, it is also possible to adopt a form in which a field plate electrode is not provided.

Further, as a modified example of the second embodiment, for example, as in the fourth modified example of the first embodiment, a planar gate type MOSFET without a trench can be used.

Further, as a modified example of the second embodiment, for example, as in the fifth modified example of the first embodiment, it is also possible to adopt a form in which the gate electrode is divided into two parts in the second direction.

As described above, according to the second embodiment and the modified examples, it is possible to implement a semiconductor device with improved avalanche capability.

### Third Embodiment

A semiconductor device according to a third embodiment is different from the semiconductor devices according to the first embodiment and the second embodiment in that the semiconductor device further includes an element region including a third semiconductor region and a termination region that does not include the third semiconductor region and surrounds the element region, a first portion is provided in the element region, and a second portion is provided in the termination region. Hereinafter, a description of contents overlapping the first embodiment or the second embodiment may be partially omitted.

The semiconductor device according to the third embodiment is a MOSFET 300. The MOSFET 300 is a vertical trench gate type MOSFET in which a gate electrode and a field plate electrode are provided in a trench.

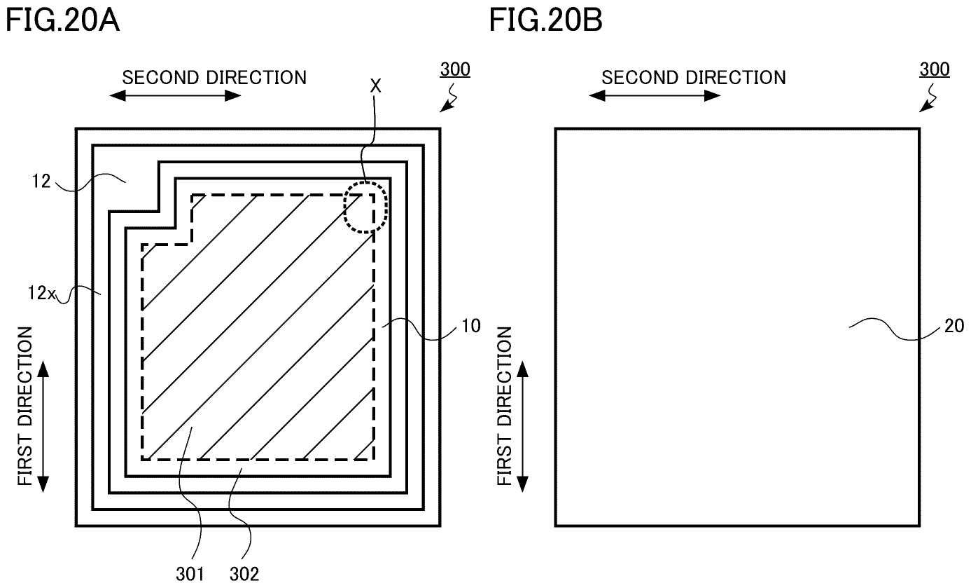

FIGS. 20A and 20B are schematic views of the semiconductor device according to the third embodiment. FIG. 20A illustrates a front surface of the MOSFET 300. FIG. 20B illustrates a back surface of the MOSFET 300.

As illustrated in FIG. 20A, a source electrode 10, a gate electrode pad 12, and a gate electrode wiring 12x are provided on a front surface side of the MOSFET 300. The gate electrode wiring 12x is connected to the gate electrode pad 12.

As illustrated in FIG. 20B, a drain electrode 20 is provided on a back surface side of the MOSFET 300.

A plurality of transistors are provided under the source electrode 10. The gate electrode pad 12 and the gate electrode wiring 12x are electrically connected to a gate electrode of the transistor. A gate voltage for controlling a switching operation of the transistor is applied to the gate electrode pad 12.

As illustrated in FIG. 20A, the MOSFET 300 includes an element region 301 and a termination region 302. The termination region 302 surrounds the element region 301. In FIG. 20A, a hatched region is the element region 301, and an outer periphery of the element region 301 is the termination region 302.

The element region 301 includes the transistor. The element region 301 includes a source region 36 of the transistor. The termination region 302 does not include the transistor. The termination region 302 does not include the source region 36.

The termination region 302 includes, for example, a termination structure for improving a breakdown voltage of the MOSFET 300. The termination structure is, for example, a RESURF structure or a guard ring structure.

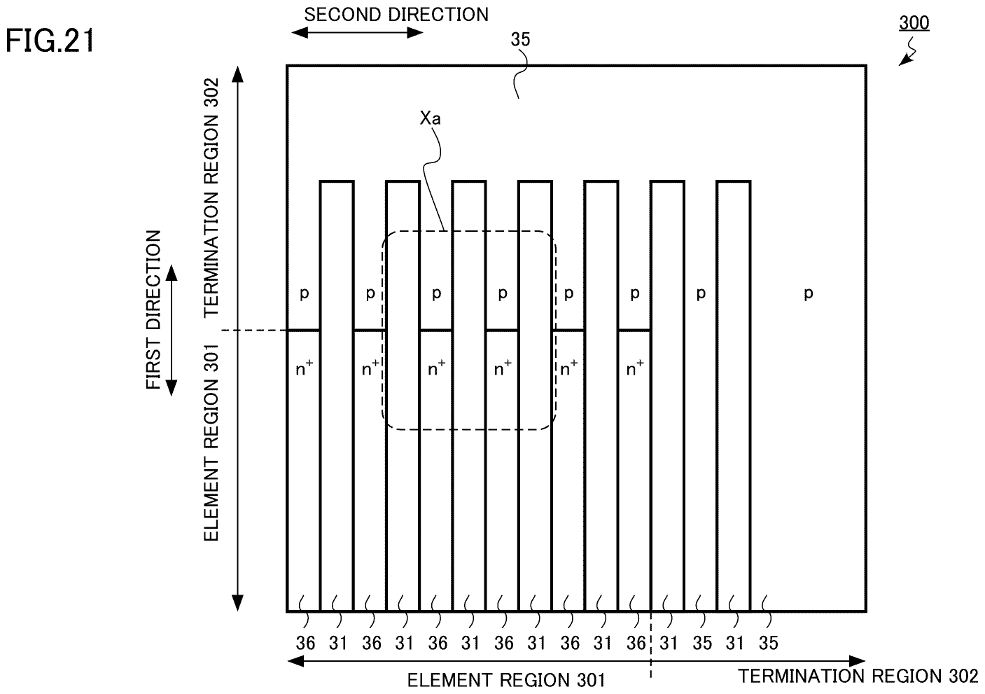

FIG. 21 is a schematic top view of a part of the semiconductor device according to the third embodiment. FIG. 21 is a view illustrating a region X in FIG. 20A. FIG. 21 is a view including a boundary between the element region 301 and the termination region 302.

FIG. 21 is a view illustrating a layout pattern of the MOSFET 300. FIG. 21 illustrates a layout pattern of a trench 31, a body region 35, and the source region 36. FIG. 21 illustrates a layout pattern on a surface of a semiconductor layer 30.

As illustrated in FIG. 21, a plurality of trenches 31 extend in a first direction. Some trenches 31 extend in the first direction beyond the boundary between the element region 301 and the termination region 302. A trench 31 at an end portion in a second direction is entirely provided outside the element region 301.

As illustrated in FIG. 21, the source region 36 is provided on the surface of the semiconductor layer 30 in the element region 301. On the other hand, the source region 36 is not provided on the surface of the semiconductor layer 30 in the termination region 302. The body region 35 is provided on the surface of the semiconductor layer 30 in the termination region 302.

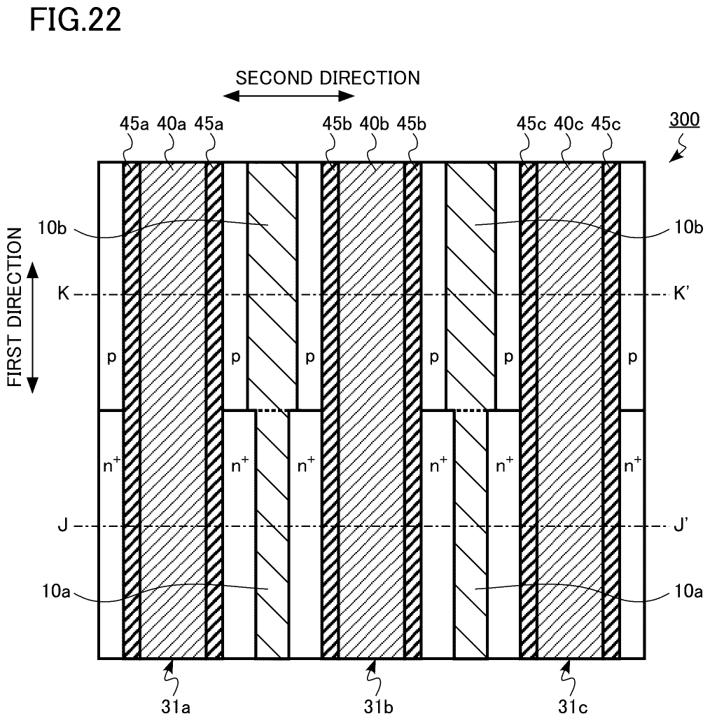

FIG. 22 is a schematic top view of a part of the semiconductor device according to the third embodiment. FIG. 22 is a view corresponding to a region Xa in FIG. 21. FIG. 21 is a view including a boundary between the element region 301 and the termination region 302.

FIG. 22 is a view of a position corresponding to a first face F1 on the semiconductor layer 30. FIG. 22 is a view excluding components on and above the first face F1.

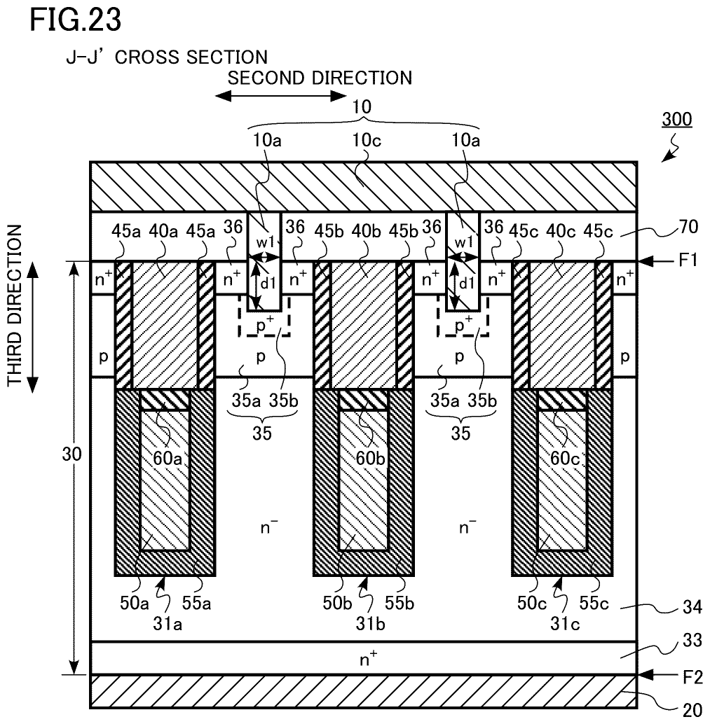

FIG. 23 is a schematic cross-sectional view of a part of the semiconductor device according to the third embodiment. FIG. 23 illustrates a cross section taken along line J-J′ in FIG. 22.

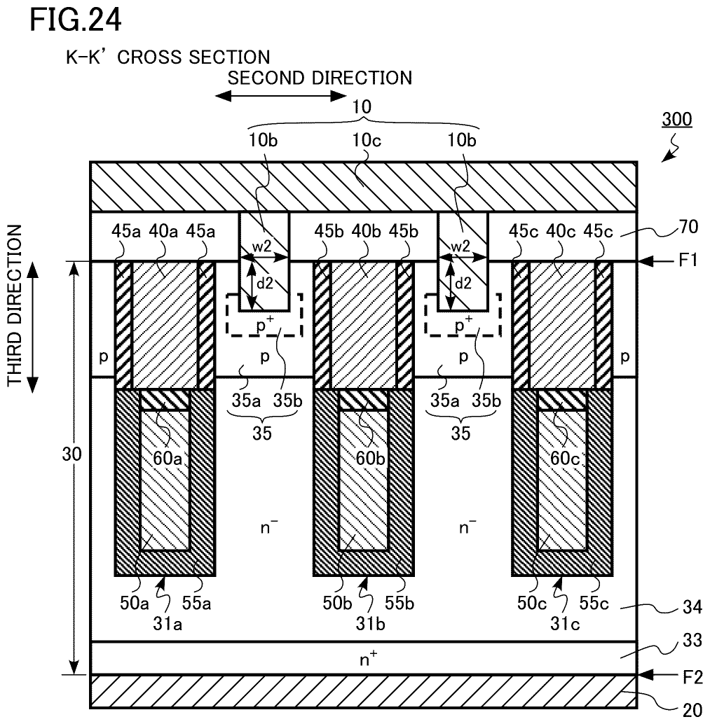

FIG. 24 is a schematic cross-sectional view of a part of the semiconductor device according to the third embodiment. FIG. 24 illustrates a cross section taken along line K-K′ in FIG. 22.

The source electrode 10 includes a first contact portion 10a, a second contact portion 10b, and a surface layer portion 10c.

The first contact portion 10a is provided in the element region 301. The second contact portion 10b is provided in the termination region 302.

The first contact portion 10a is provided between the semiconductor layer 30 and the surface layer portion 10c. The first contact portion 10a is provided between two gate electrodes 40 adjacent to each other in the second direction. The first contact portion 10a is provided, for example, between a first gate electrode 40a and a second gate electrode 40b. The first contact portion 10a is provided, for example, between the second gate electrode 40b and a third gate electrode 40c.

The first contact portion 10a is in contact with the semiconductor layer 30. The first contact portion 10a is in contact with the body region 35. For example, a bottom face and side faces of the first contact portion 10a are in contact with the body region 35. For example, the first contact portion 10a is in contact with a high-concentration region 35b of the body region 35. For example, the bottom face and the side faces of the first contact portion 10a are in contact with the high-concentration region 35b of the body region 35.

A first contact portion 10a is in contact with a source region 36. For example, side faces of the first contact portion 10a are in contact with the source region 36.

The first contact portion 10a is sandwiched between a part and another part of the semiconductor layer 30 in the second direction. For example, the first contact portion 10a is sandwiched between the source region 36 and the source region 36 in the second direction.

A width of the first contact portion 10a in the second direction is a first width (w1 in FIG. 23). The first width w1 of the first contact portion 10a in the second direction is, for example, a width in the second direction at a position corresponding to the first face F1 on the first contact portion 10a.

A depth of the first contact portion 10a in a third direction is a first depth (d1 in FIG. 23). The depth of the first contact portion 10a in the third direction is a depth from the first face F1.

The first depth d1 of the first contact portion 10a is larger than a depth of the source region 36, for example.

The second contact portion 10b is provided between the semiconductor layer 30 and the surface layer portion 10c. The second contact portion 10b is provided between two gate electrodes 40 adjacent to each other in the second direction. The second contact portion 10b is provided, for example, between the first gate electrode 40a and the second gate electrode 40b. The second contact portion 10b is provided, for example, between the second gate electrode 40b and the third gate electrode 40c.

The second contact portion 10b is provided in the first direction with respect to the first contact portion 10a.

The second contact portion 10b is in contact with the semiconductor layer 30. The second contact portion 10b is in contact with the body region 35. For example, a bottom face and side faces of the second contact portion 10b are in contact with the body region 35. For example, the second contact portion 10b is in contact with the high-concentration region 35b of the body region 35. For example, the bottom face and the side faces of the second contact portion 10b are in contact with the high-concentration region 35b of the body region 35.

A second contact portion 10b is not in contact with the source region 36. The source region 36 is not provided around the second contact portion 10b.

The second contact portion 10b is sandwiched between a part and another part of the semiconductor layer 30 in the second direction. For example, the second contact portion 10b is sandwiched between the body region 35 and the body region 35 in the second direction.

A width of the second contact portion 10b in the second direction is a second width (w2 in FIG. 24). The second width w2 of the second contact portion 10b in the second direction is, for example, a width in the second direction at a position corresponding to the first face F1 on the second contact portion 10b.

The second width w2 of the second contact portion 10b is larger than the first width w1 of the first contact portion 10a. The second width w2 is, for example, 1.2 times or more and 3 times or less the first width w1.

A depth of the second contact portion 10b in the third direction is a second depth (d2 in FIG. 24). The depth of the second contact portion 10b in the third direction is a depth from the first face F1.

The second depth d2 of the second contact portion 10b is larger than the depth of the source region 36, for example.

The second depth d2 of the second contact portion 10b is, for example, substantially the same as the first depth d1 of the first contact portion 10a.

The surface layer portion 10c is provided on a plurality of first contact portions 10a and a plurality of second contact portions 10b. The surface layer portion 10c electrically connects the plurality of first contact portions 10a and the plurality of second contact portions 10b.

The surface layer portion 10c is a region to which a bonding wire is connected, for example, when the MOSFET 300 is mounted.

Next, functions and effects of the semiconductor device according to the third embodiment will be described.

In the MOSFET 300 according to the third embodiment, the second width w2 of the second contact portion 10b provided in the termination region 302 is larger than the first width w1 of the first contact portion 10a provided in the element region 301. Discharge of holes from the second contact portion 10b is promoted by increasing the second width w2 of the second contact portion 10b. Therefore, avalanche capability of the MOSFET 300 is improved.

In the MOSFET 300, the second contact portion 10b is provided only in the termination region 302 not including the transistor. The second contact portion 10b is not provided in the element region 301 where the transistor is provided. Therefore, an on-current of the MOSFET 300 is not changed due to the provided second contact portion 10b.

From the viewpoint of improving the avalanche capability of the MOSFET 300, the second width w2 of the second contact portion 10b is preferably 1.2 times or more, and more preferably 1.5 times or more the first width w1 of the first contact portion 10a.

### First Modified Example

A semiconductor device according to a first modified example of the third embodiment is different from the semiconductor device according to the third embodiment in that a first width of a first portion is the same as a second width of a second portion, and a second depth of the second portion is larger than a first depth of the first portion.

The semiconductor device according to the first modified example of the third embodiment is a MOSFET 310. The MOSFET 310 is a vertical trench gate type MOSFET in which a gate electrode and a field plate electrode are provided in a trench.

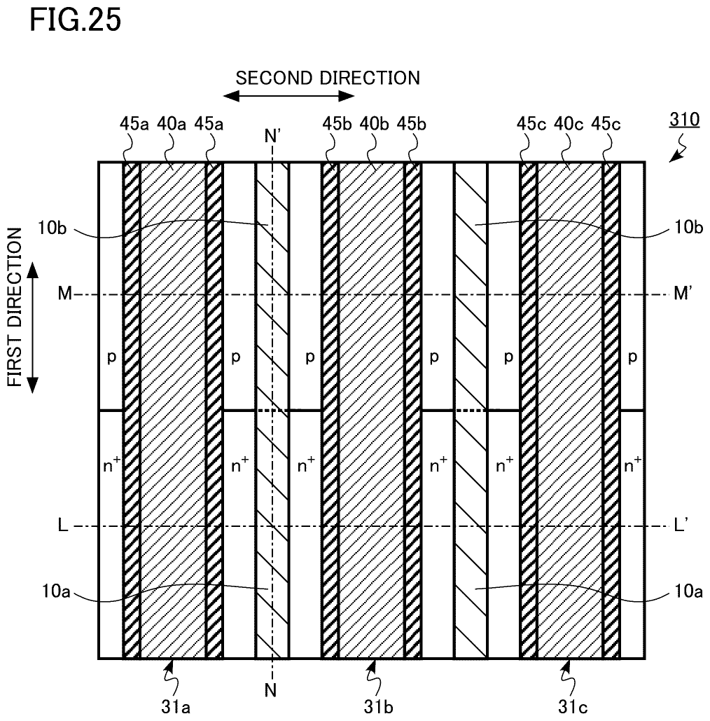

FIG. 25 is a schematic top view of a part of the semiconductor device according to the first modified example of the third embodiment. FIG. 25 is a view including a boundary between an element region 301 and a termination region 302. FIG. 25 is a view corresponding to FIG. 22 of the third embodiment.

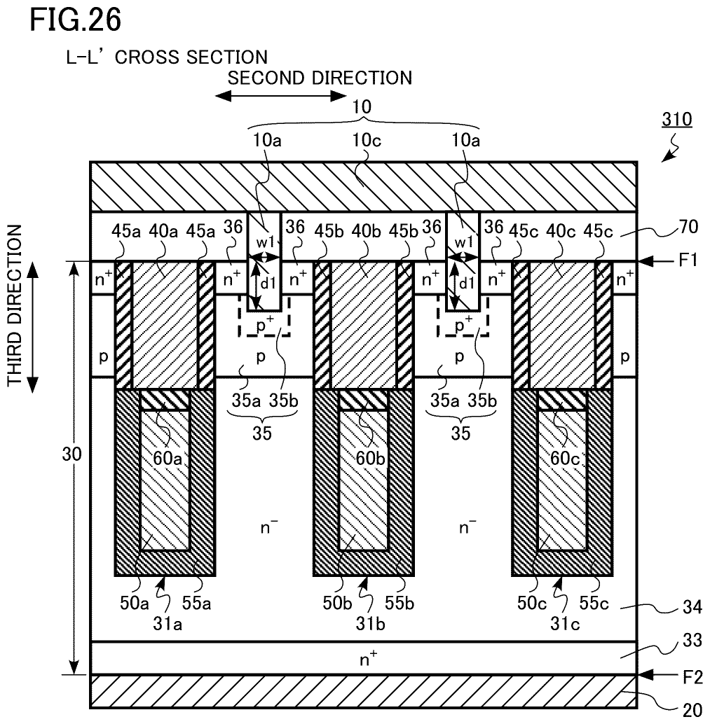

FIG. 26 is a schematic cross-sectional view of a part of the semiconductor device according to the first modified example of the third embodiment. FIG. 26 illustrates a cross section taken along line L-L′ in FIG. 25. FIG. 26 is a view corresponding to FIG. 23 of the third embodiment.

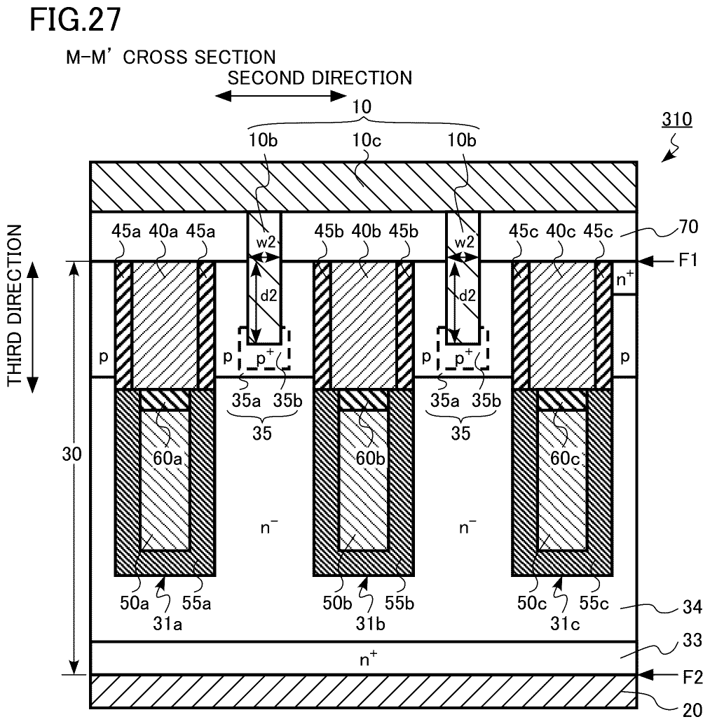

FIG. 27 is a schematic cross-sectional view of a part of the semiconductor device according to the first modified example of the third embodiment. FIG. 27 illustrates a cross section taken along line M-M′ in FIG. 25. FIG. 27 is a view corresponding to FIG. 24 of the third embodiment.

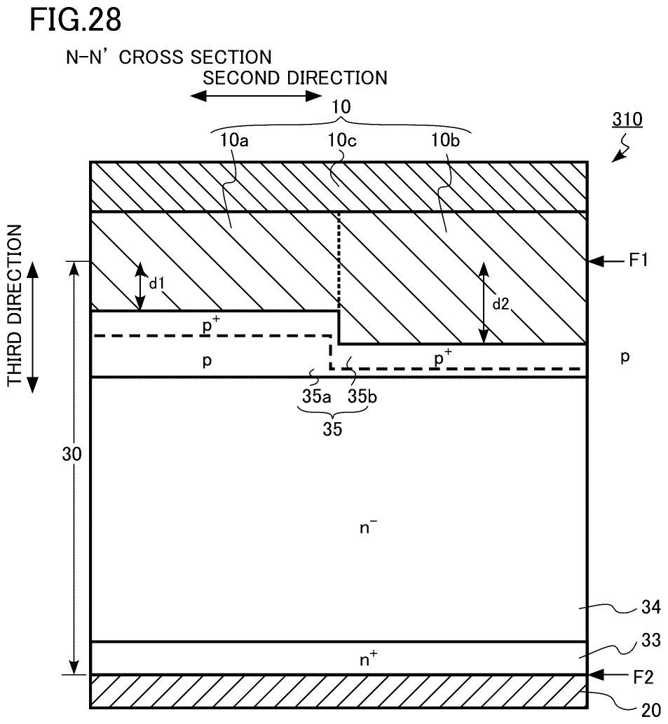

FIG. 28 is a schematic cross-sectional view of a part of the semiconductor device according to the first modified example of the third embodiment. FIG. 28 illustrates a cross section taken along line N-N′ in FIG. 25.

The source electrode 10 includes a first contact portion 10a, a second contact portion 10b, and a surface layer portion 10c.

The first contact portion 10a is provided in the element region 301. The second contact portion 10b is provided in the termination region 302.

A first contact portion 10a is in contact with a source region 36. For example, side faces of the first contact portion 10a are in contact with the source region 36.

A width of the first contact portion 10a in the second direction is a first width (w1 in FIG. 26). The first width w1 of the first contact portion 10a in the second direction is, for example, a width in the second direction at a position corresponding to the first face F1 on the first contact portion 10a.

A depth of the first contact portion 10a in a third direction is a first depth (d1 in FIG. 26). The depth of the first contact portion 10a in the third direction is a depth from the first face F1.

The first depth d1 of the first contact portion 10a is larger than a depth of the source region 36, for example.

A second contact portion 10b is not in contact with the source region 36. The source region 36 is not provided around the second contact portion 10b.

A width of the second contact portion 10b in the second direction is a second width (w2 in FIG. 27). The second width w2 of the second contact portion 10b in the second direction is, for example, a width in the second direction at a position corresponding to the first face F1 on the second contact portion 10b.

The second width w2 of the second contact portion 10b is, for example, substantially the same as the first width w1 of the first contact portion 10a.

A depth of the second contact portion 10b in the third direction is a second depth (d2 in FIG. 27). The depth of the second contact portion 10b in the third direction is a depth from the first face F1.

The second depth d2 of the second contact portion 10b is larger than the depth of the source region 36.

The second depth d2 of the second contact portion 10b is larger than the first depth d1 of the first contact portion 10a. The second depth d2 of the second contact portion 10b is, for example, 1.2 times or more and 2 times or less the first depth d1 of the first contact portion 10a.

For example, as illustrated in FIG. 25, the second contact portion 10b is provided in the first direction with respect to the first contact portion 10a between two gate electrodes 40 adjacent to each other in the second direction. As illustrated in FIG. 28, the depth of the contact portion including the first contact portion 10a and the second contact portion 10b in the third direction increases in the first direction.

In the MOSFET 310 according to the first modified example of the third embodiment, the second depth d2 of the second contact portion 10b provided in the termination region 302 is larger than the first depth d1 of the first contact portion 10a provided in the element region 301. Discharge of holes from the second contact portion 10b is promoted by increasing the second depth d2 of the second contact portion 10b. Therefore, avalanche capability of the MOSFET 310 is improved.

From the viewpoint of improving the avalanche capability of the MOSFET 310, the second depth d2 of the second contact portion 10b is preferably 1.2 times or more, and more preferably 1.5 times or more the first depth d1 of the first contact portion 10a.

As a modified example of the third embodiment, for example, as in the third modified example of the first embodiment, it is also possible to adopt a form in which a field plate electrode is not provided.

Further, as a modified example of the third embodiment, for example, as in the fourth modified example of the first embodiment, a planar gate type MOSFET without a trench can be used.

Further, as a modified example of the third embodiment, for example, as in the fifth modified example of the first embodiment, it is also possible to adopt a form in which the gate electrode is divided into two parts in the second direction.

Further, as a modified example of the third embodiment, for example, as in the second modified example of the second embodiment, it is also possible to adopt a form in which the second depth d2 of the second contact portion 10b is larger than the first depth d1 of the first contact portion 10a, and the second width w2 of the second contact portion 10b is larger than the first width w1 of the first contact portion 10a.

As described above, according to the third embodiment and the modified examples, it is possible to implement a semiconductor device with improved avalanche capability.

### Fourth Embodiment

A semiconductor device according to a fourth embodiment includes: a semiconductor layer having a first face and a second face facing the first face and including a first semiconductor region of a first conductivity type, a second semiconductor region of a second conductivity type provided between the first semiconductor region and the first face, and a third semiconductor region of the first conductivity type provided between the second semiconductor region and the first face; a first gate electrode provided on a side of the semiconductor layer and extending in a first direction parallel to the first face, the side being adjacent to the first face; a second gate electrode provided on the side of the semiconductor layer, extending in the first direction, and provided in a second direction parallel to the first face and perpendicular to the first direction with respect to the first gate electrode, the side being adjacent to the first face; a third gate electrode provided on the side of the semiconductor layer, extending in the first direction, and having the second gate electrode provided between the third gate electrode and the first gate electrode, the side being adjacent to the first face; a first gate insulating layer provided between the first gate electrode and the semiconductor layer; a second gate insulating layer provided between the second gate electrode and the semiconductor layer; a third gate insulating layer provided between the third gate electrode and the semiconductor layer; a first electrode provided on the side of the semiconductor layer and electrically connected to the third semiconductor region, the side being adjacent to the first face; and a second electrode provided on a side of the semiconductor layer and electrically connected to the first semiconductor region, the side being adjacent to the second face. The first electrode includes a first portion and a second portion, the first portion is provided between the first gate electrode and the second gate electrode, the second portion is provided between the second gate electrode and the third gate electrode, the second portion is provided in the second direction with respect to the first portion, the first portion is in contact with the second semiconductor region and the third semiconductor region, the second portion is in contact with the second semiconductor region and not in contact with the third semiconductor region, the first portion is sandwiched between a part and another part of the semiconductor layer in the second direction, the second portion is sandwiched between a part and another part of the semiconductor layer in the second direction, and a second width of the second portion in the second direction is larger than a first width of the first portion in the second direction, or a second depth of the second portion is larger than a first depth of the first portion. The semiconductor device according to the fourth embodiment is different from the semiconductor devices of the first embodiment, the second embodiment, and the third embodiment in that the first portion is not provided between two gate electrodes that are the same as those of the second portion. Hereinafter, a description of contents overlapping the first embodiment, the second embodiment, or the third embodiment may be partially omitted.

The semiconductor device according to the fourth embodiment is a MOSFET 400. The MOSFET 400 is a vertical trench gate type MOSFET in which a gate electrode and a field plate electrode are provided in a trench.

The MOSFET 400 includes a source electrode 10 (first electrode), a drain electrode 20 (second electrode), a semiconductor layer 30, a first gate electrode 40a, a second gate electrode 40b, a third gate electrode 40c, a first gate insulating layer 45a, a second gate insulating layer 45b, a third gate insulating layer 45c, a first field plate electrode 50a, a second field plate electrode 50b, a third field plate electrode 50c, a first field plate insulating layer 55a, a second field plate insulating layer 55b, a third field plate insulating layer 55c, a first inter-electrode insulating layer 60a, a second inter-electrode insulating layer 60b, a third inter-electrode insulating layer 60c, and an interlayer insulating layer 70.

Hereinafter, the first gate electrode 40a, the second gate electrode 40b, and the third gate electrode 40c may be simply referred to as a gate electrode 40 individually or collectively. In addition, the first gate insulating layer 45a, the second gate insulating layer 45b, and the third gate insulating layer 45c may be simply referred to as a gate insulating layer 45 individually or collectively. The first field plate electrode 50a, the second field plate electrode 50b, and the third field plate electrode 50c may be simply referred to as a field plate electrode 50 individually or collectively. The first field plate insulating layer 55a, the second field plate insulating layer 55b, and the third field plate insulating layer 55c may be simply referred to as a field plate insulating layer 55 individually or collectively. The first inter-electrode insulating layer 60a, the second inter-electrode insulating layer 60b, and the third inter-electrode insulating layer 60c may be simply referred to as an inter-electrode insulating layer 60 individually or collectively.

The source electrode 10 includes a first contact portion 10a (first portion), a second contact portion 10b (second portion), and a surface layer portion 10c. The semiconductor layer 30 includes a first trench 31a, a second trench 31b, a third trench 31c, a drain region 33 of n⁺ type, a drift region 34 (first semiconductor region) of n-type, a body region 35 (second semiconductor region) of p type, and a source region 36 (third semiconductor region) of n⁺ type.

Hereinafter, the first trench 31a, the second trench 31b, and the third trench 31c may be simply referred to as a trench 31 individually or collectively.

The body region 35 includes a low-concentration region 35a (first region) and a high-concentration region 35b (second region).

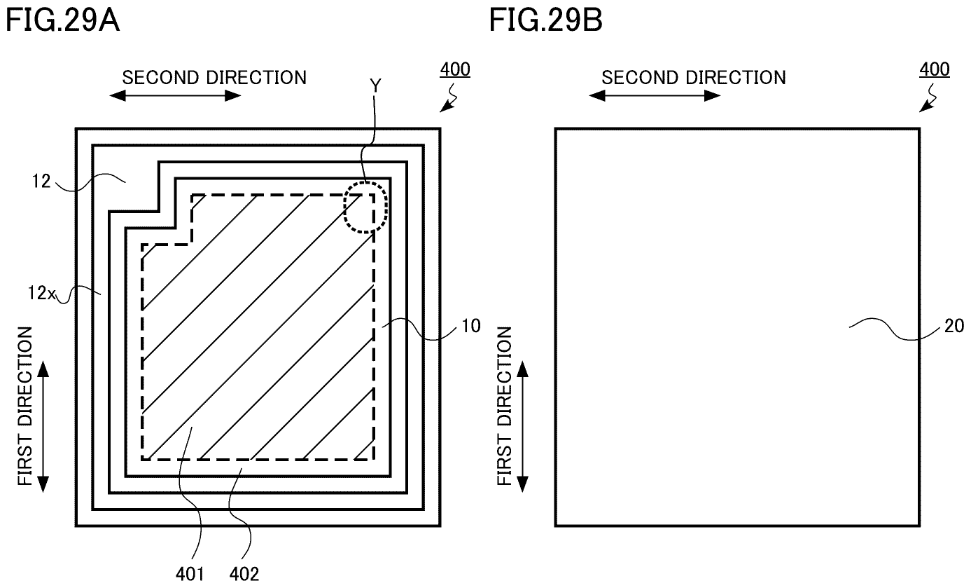

FIGS. 29A and 29B are schematic views of the semiconductor device according to the fourth embodiment. FIG. 29A illustrates a front surface of the MOSFET 400. FIG. 29B illustrates a back surface of the MOSFET 400.

As illustrated in FIG. 29A, the source electrode 10, a gate electrode pad 12, and a gate electrode wiring 12x are provided on a front surface side of the MOSFET 400. The gate electrode wiring 12x is connected to the gate electrode pad 12.

As illustrated in FIG. 29B, the drain electrode 20 is provided on a back surface side of the MOSFET 400.

A plurality of transistors are provided under the source electrode 10. The gate electrode pad 12 and the gate electrode wiring 12x are electrically connected to a gate electrode of the transistor. A gate voltage for controlling a switching operation of the transistor is applied to the gate electrode pad 12.

As illustrated in FIG. 29A, the MOSFET 400 includes an element region 401 and a termination region 402. The termination region 402 surrounds the element region 401. In FIG. 29A, a hatched region is the element region 401, and an outer periphery of the element region 401 is the termination region 402.

The element region 401 includes the transistor. The element region 401 includes the source region 36 of the transistor. The termination region 402 does not include the transistor. The termination region 402 does not include the source region 36.

The termination region 402 includes, for example, a termination structure for improving a breakdown voltage of the MOSFET 400. The termination structure is, for example, a RESURF structure or a guard ring structure.

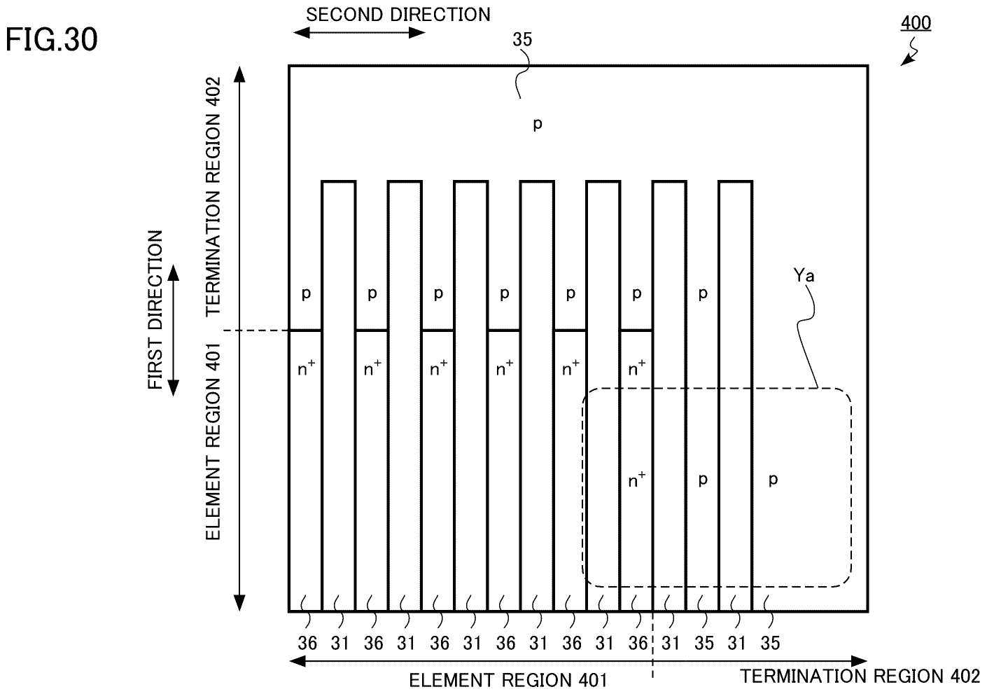

FIG. 30 is a schematic top view of a part of the semiconductor device according to the fourth embodiment. FIG. 30 is a view illustrating a region Y in FIG. 29A. FIG. 30 is a view including a boundary between the element region 401 and the termination region 402.

FIG. 30 is a view illustrating a layout pattern of the MOSFET 400. FIG. 30 illustrates a layout pattern of the trench 31, the body region 35, and the source region 36. FIG. 30 illustrates a layout pattern on a surface of the semiconductor layer 30.

As illustrated in FIG. 30, a plurality of trenches 31 extend in the first direction. Among the plurality of trenches 31, a trench 31 disposed at an end portion in the second direction is entirely provided outside the element region 401. Among the plurality of trenches 31, the trench 31 disposed at the end portion in the second direction is provided in the termination region 402.

As illustrated in FIG. 30, the source region 36 is provided on the surface of the semiconductor layer 30 in the element region 401. On the other hand, the source region 36 is not provided on the surface of the semiconductor layer 30 in the termination region 402. The body region 35 is provided on the surface of the semiconductor layer 30 in the termination region 402.

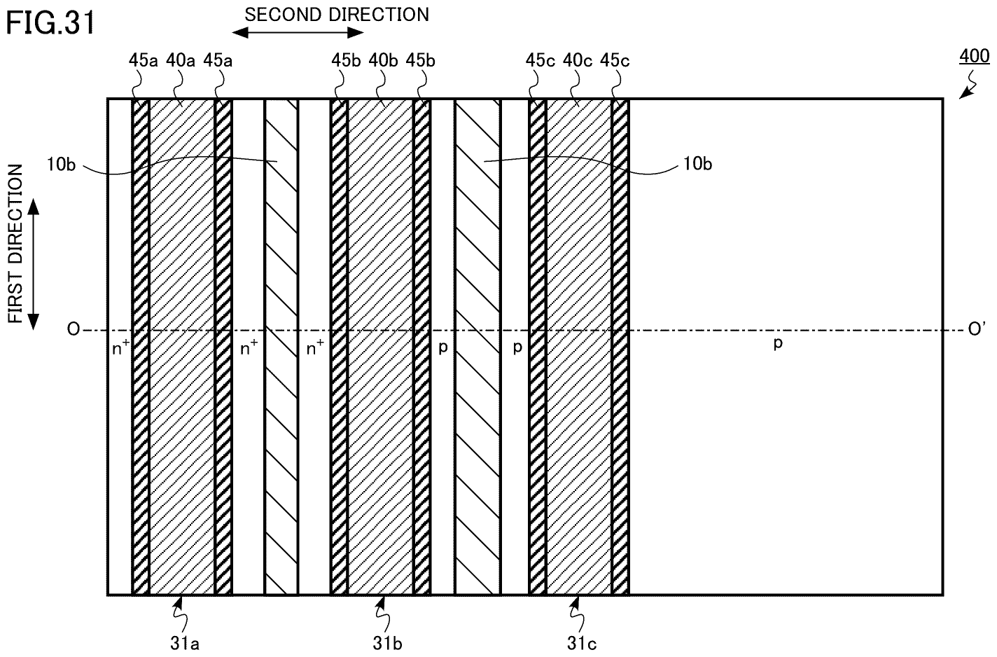

FIG. 31 is a schematic top view of a part of the semiconductor device according to the fourth embodiment. FIG. 31 is a view corresponding to a region Ya in FIG. 30. FIG. 31 is a view including a boundary between the element region 401 and the termination region 402.

FIG. 31 is a view of a position corresponding to a first face F1 on the semiconductor layer 30. FIG. 31 is a view excluding components on and above the first face F1.

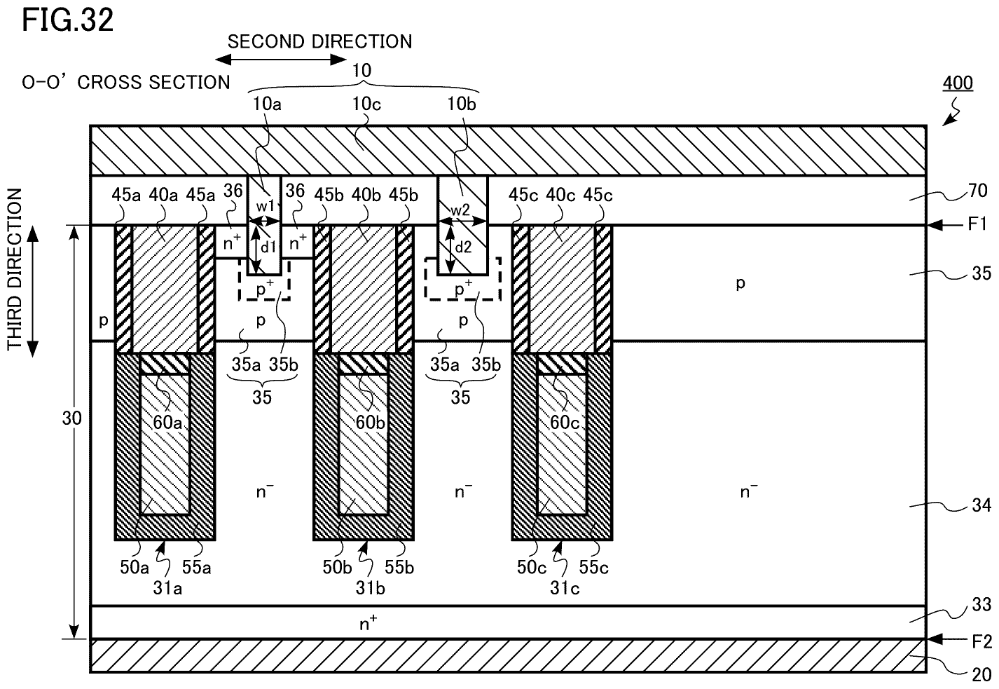

FIG. 32 is a schematic cross-sectional view of a part of the semiconductor device according to the fourth embodiment. FIG. 32 illustrates a cross section taken along line O-O′ in FIG. 31.

At least a part of the first gate electrode 40a is provided in the element region 401. The entire third gate electrode 40c is provided in the termination region 402. The second gate electrode 40b is provided between the first gate electrode 40a and the third gate electrode 40c.

A portion of the semiconductor layer 30 whose position in the second direction is a position between the first gate electrode 40a and the second gate electrode 40b includes the source region 36. Another portion of the semiconductor layer 30 whose position in the second direction is a position between the second gate electrode 40b and the third gate electrode 40c does not include the source region 36.

The semiconductor layer 30 between the first trench 31a and the second trench 31b includes the source region 36. The semiconductor layer 30 between the second trench 31b and the third trench 31c does not include the source region 36.

The source electrode 10 includes a first contact portion 10a, a second contact portion 10b, and a surface layer portion 10c.

The first contact portion 10a is provided in the element region 401. The second contact portion 10b is provided in the termination region 402. The second contact portion 10b is provided in the second direction with respect to the first contact portion 10a.

The first contact portion 10a is provided between the semiconductor layer 30 and the surface layer portion 10c. The first contact portion 10a is provided between the first gate electrode 40a and the second gate electrode 40b. The first contact portion 10a is not provided between the second gate electrode 40b and the third gate electrode 40c.

The first contact portion 10a is in contact with the semiconductor layer 30. The first contact portion 10a is in contact with the body region 35. For example, a bottom face and side faces of the first contact portion 10a are in contact with the body region 35. For example, the first contact portion 10a is in contact with a high-concentration region 35b of the body region 35. For example, the bottom face and the side faces of the first contact portion 10a are in contact with the high-concentration region 35b of the body region 35.

A first contact portion 10a is in contact with a source region 36. For example, side faces of the first contact portion 10a are in contact with the source region 36.

The first contact portion 10a is sandwiched between a part and another part of the semiconductor layer 30 in the second direction. For example, the first contact portion 10a is sandwiched between the source region 36 and the source region 36 in the second direction.

A width of the first contact portion 10a in the second direction is a first width (w1 in FIG. 32). The first width w1 of the first contact portion 10a in the second direction is, for example, a width in the second direction at a position corresponding to the first face F1 on the first contact portion 10a.

A depth of the first contact portion 10a in a third direction is a first depth (d1 in FIG. 32). The depth of the first contact portion 10a in the third direction is a depth from the first face F1.

The first depth d1 of the first contact portion 10a is larger than a depth of the source region 36, for example.

The second contact portion 10b is provided between the semiconductor layer 30 and the surface layer portion 10c. The second contact portion 10b is provided between the second gate electrode 40b and the third gate electrode 40c. The second contact portion 10b is not provided, for example, between the first gate electrode 40a and the second gate electrode 40b.

The second contact portion 10b is provided in the second direction with respect to the first contact portion 10a.

The second contact portion 10b is in contact with the semiconductor layer 30. The second contact portion 10b is in contact with the body region 35. For example, a bottom face and side faces of the second contact portion 10b are in contact with the body region 35. For example, the second contact portion 10b is in contact with the high-concentration region 35b of the body region 35. For example, the bottom face and the side faces of the second contact portion 10b are in contact with the high-concentration region 35b of the body region 35.

A second contact portion 10b is not in contact with the source region 36. The source region 36 is not provided around the second contact portion 10b.

The second contact portion 10b is sandwiched between a part and another part of the semiconductor layer 30 in the second direction. For example, the second contact portion 10b is sandwiched between the body region 35 and the body region 35 in the second direction.

A width of the second contact portion 10b in the second direction is a second width (w2 in FIG. 32). The second width w2 of the second contact portion 10b in the second direction is, for example, a width in the second direction at a position corresponding to the first face F1 on the second contact portion 10b.

The second width w2 of the second contact portion 10b is larger than the first width w1 of the first contact portion 10a. The second width w2 is, for example, 1.2 times or more and 3 times or less the first width w1.

A depth of the second contact portion 10b in the third direction is a second depth (d2 in FIG. 32). The depth of the second contact portion 10b in the third direction is a depth from the first face F1.

The second depth d2 of the second contact portion 10b is, for example, substantially the same as the first depth d1 of the first contact portion 10a.

The surface layer portion 10c is provided on the first contact portion 10a and the second contact portion 10b. The surface layer portion 10c electrically connects the plurality of first contact portions 10a and the plurality of second contact portions 10b.

The surface layer portion 10c is a region to which a bonding wire is connected, for example, when the MOSFET 400 is mounted.

Next, functions and effects of the semiconductor device according to the fourth embodiment will be described.

In the MOSFET 400 according to the fourth embodiment, the second width w2 of the second contact portion 10b provided in the termination region 402 is larger than the first width w1 of the first contact portion 10a provided in the element region 401. Discharge of holes from the second contact portion 10b is promoted by increasing the second width w2 of the second contact portion 10b. Therefore, avalanche capability of the MOSFET 400 is improved.

In the MOSFET 400, the second contact portion 10b is provided only in the termination region 402 not including the transistor. The second contact portion 10b is not provided in the element region 401 where the transistor is provided. Therefore, an on-current of the MOSFET 400 is not changed due to the provided second contact portion 10b.

From the viewpoint of improving the avalanche capability of the MOSFET 400, the second width w2 of the second contact portion 10b is preferably 1.2 times or more, and more preferably 1.5 times or more the first width w1 of the first contact portion 10a.

### First Modified Example

A semiconductor device according to a first modified example of the fourth embodiment is different from the semiconductor device according to the fourth embodiment in that a first width of a first portion and a second width of a second portion are the same, and a second depth of the second portion is larger than a first depth of the first portion.

The semiconductor device according to the first modified example of the fourth embodiment is a MOSFET 410. The MOSFET 410 is a vertical trench gate type MOSFET in which a gate electrode and a field plate electrode are provided in a trench.

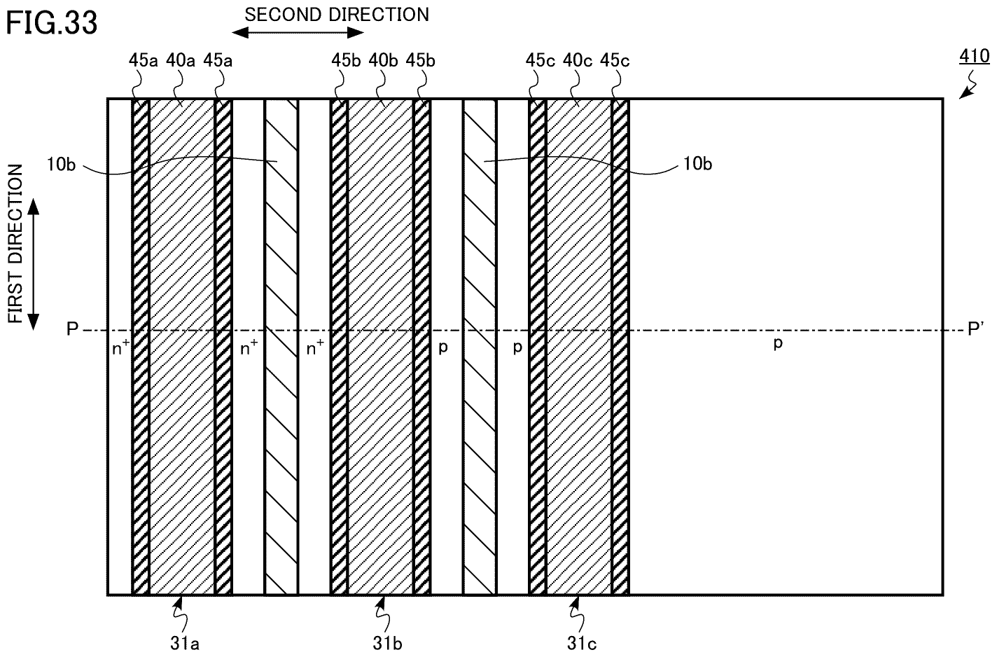

FIG. 33 is a schematic top view of a part of the semiconductor device according to the first modified example of the fourth embodiment. FIG. 33 is a view including a boundary between an element region 401 and a termination region 402. FIG. 33 is a view corresponding to FIG. 31 of the fourth embodiment.

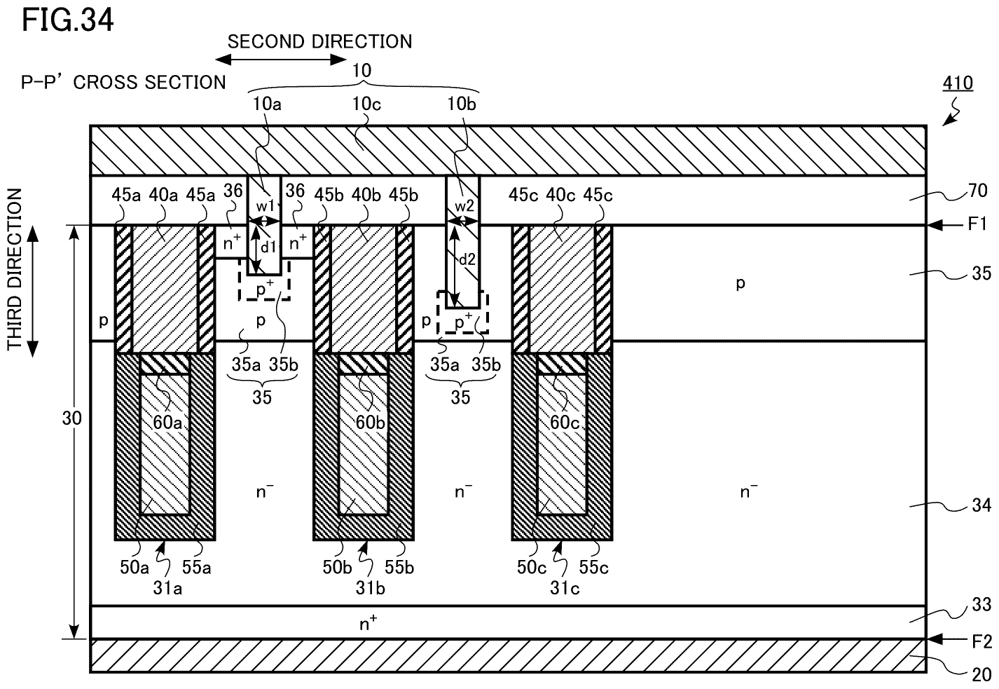

FIG. 34 is a schematic cross-sectional view of a part of the semiconductor device according to the first modified example of the fourth embodiment. FIG. 34 illustrates a cross section taken along line P-P′ in FIG. 33. FIG. 34 is a view corresponding to FIG. 32 of the fourth embodiment.

The source electrode 10 includes a first contact portion 10a, a second contact portion 10b, and a surface layer portion 10c.

The first contact portion 10a is provided in the element region 401. The second contact portion 10b is provided in the termination region 402.

A first contact portion 10a is in contact with a source region 36. For example, side faces of the first contact portion 10a are in contact with the source region 36.

A width of the first contact portion 10a in the second direction is a first width (w1 in FIG. 34). The first width w1 of the first contact portion 10a in the second direction is, for example, a width in the second direction at a position corresponding to the first face F1 on the first contact portion 10a.

A depth of the first contact portion 10a in the third direction is a first depth (d1 in FIG. 34). The depth of the first contact portion 10a in the third direction is a depth from the first face F1.

The first depth d1 of the first contact portion 10a is larger than a depth of the source region 36, for example.

A second contact portion 10b is not in contact with the source region 36. The source region 36 is not provided around the second contact portion 10b.

A width of the second contact portion 10b in the second direction is a second width (w2 in FIG. 34). The second width w2 of the second contact portion 10b in the second direction is, for example, a width in the second direction at a position corresponding to the first face F1 on the second contact portion 10b.

The second width w2 of the second contact portion 10b is, for example, substantially the same as the first width w1 of the first contact portion 10a.

A depth of the second contact portion 10b in the third direction is the second depth (d2 in FIG. 34). The depth of the second contact portion 10b in the third direction is a depth from the first face F1.

The second depth d2 of the second contact portion 10b is larger than the first depth d1 of the first contact portion 10a. The second depth d2 of the second contact portion 10b is, for example, 1.2 times or more and 2 times or less the first depth d1 of the first contact portion 10a.

The second contact portion 10b is provided in the second direction with respect to the first contact portion 10a.

In the MOSFET 410 according to the first modified example of the fourth embodiment, the second depth d2 of the second contact portion 10b provided in the termination region 402 is larger than the first depth d1 of the first contact portion 10a provided in the element region 401. Discharge of holes from the second contact portion 10b is promoted by increasing the second depth d2 of the second contact portion 10b. Therefore, avalanche capability of the MOSFET 410 is improved.

From the viewpoint of improving the avalanche capability of the MOSFET 410, the second depth d2 of the second contact portion 10b is preferably 1.2 times or more, and more preferably 1.5 times or more the first depth d1 of the first contact portion 10a.

As a modified example of the fourth embodiment, for example, as in the third modified example of the first embodiment, it is also possible to adopt a form in which a field plate electrode is not provided.

Further, as a modified example of the fourth embodiment, for example, as in the fourth modified example of the first embodiment, a planar gate type MOSFET without a trench can be used.

Further, as a modified example of the fourth embodiment, for example, as in the fifth modified example of the first embodiment, it is also possible to adopt a form in which the gate electrode is divided into two parts in the second direction.

Further, as a modified example of the fourth embodiment, for example, as in the second modified example of the second embodiment, it is also possible to adopt a form in which the second depth d2 of the second contact portion 10b is larger than the first depth d1 of the first contact portion 10a, and the second width w2 of the second contact portion 10b is larger than the first width w1 of the first contact portion 10a.

Furthermore, as a modified example of the fourth embodiment, for example, the fourth embodiment and the third embodiment can be combined.

As described above, according to the fourth embodiment and the modified examples, it is possible to implement a semiconductor device with improved avalanche capability.

In the first to fourth embodiments, a case where the semiconductor layer is single crystal silicon has been described as an example, but the semiconductor layer is not limited to single crystal silicon. For example, other single crystal semiconductors such as single crystal silicon carbide may be used.

In the first to fourth embodiments, a case where the first conductivity type is n type and the second conductivity type is p type has been described as an example, but the first conductivity type may be p type and the second conductivity type may be n type. That is, the MOSFET may be a MOSFET of a p-channel type using a hole as a carrier.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer having a first face and a second face facing the first face, and including
a first semiconductor region of a first conductivity type,
a second semiconductor region of a second conductivity type provided between the first semiconductor region and the first face, and
a third semiconductor region of the first conductivity type provided between the second semiconductor region and the first face;
a first gate electrode provided on a first face side of the semiconductor layer and extending in a first direction parallel to the first face;
a second gate electrode provided on the first face side of the semiconductor layer and extending in the first direction, and provided in a second direction parallel to the first face and perpendicular to the first direction with respect to the first gate electrode;
a first gate insulating layer provided between the first gate electrode and the semiconductor layer;
a second gate insulating layer provided between the second gate electrode and the semiconductor layer;
a first electrode provided on the first face side of the semiconductor layer and electrically connected to the third semiconductor region; and
a second electrode provided on a second face side of the semiconductor layer and electrically connected to the first semiconductor region, wherein
the first electrode includes a first portion and a second portion,
the first portion and the second portion are provided between the first gate electrode and the second gate electrode,
the first portion and the second portion are in contact with the second semiconductor region,
the second portion is provided in the first direction with respect to the first portion,
the first portion is sandwiched between a part and another part of the semiconductor layer in the second direction,
the second portion is sandwiched between a part and another part of the semiconductor layer in the second direction, and
a second width of the second portion in the second direction is larger than a first width of the first portion in the second direction, or a second depth of the second portion is larger than a first depth of the first portion.

2. The semiconductor device according to claim 1, wherein the first electrode includes a plurality of the first portions and a plurality of the second portions, and the first portion and the second portion are alternately provided in a repeated pattern in the first direction.

3. The semiconductor device according to claim 1, wherein the first portion is in contact with the third semiconductor region, and the second portion is not in contact with the third semiconductor region.

4. The semiconductor device according to claim 1, wherein
the semiconductor layer further includes a first trench provided on the first face side of the semiconductor layer and extending in the first direction, and a second trench provided on the first face side of the semiconductor layer and extending in the first direction,
the first gate electrode is provided in the first trench, and
the second gate electrode is provided in the second trench.

5. The semiconductor device according to claim 4, further comprising:
a first field plate electrode provided in the first trench and provided between the first gate electrode and the second face;
a second field plate electrode provided in the second trench and provided between the second gate electrode and the second face;
a first field plate insulating layer provided between the first field plate electrode and the semiconductor layer;
a second field plate insulating layer provided between the second field plate electrode and the semiconductor layer;
a first inter-electrode insulating layer provided between the first gate electrode and the first field plate electrode; and
a second inter-electrode insulating layer provided between the second gate electrode and the second field plate electrode.

6. The semiconductor device according to claim 1, further comprising:
an element region including the third semiconductor region; and
a termination region not including the third semiconductor region and surrounding the element region,
wherein the first portion is provided in the element region, and the second portion is provided in the termination region.

7. The semiconductor device according to claim 1, wherein the second width is 1.2 times or more and 3 times or less the first width.

8. The semiconductor device according to claim 1, wherein the second depth is 1.2 times or more and 2 times or less the first depth.

9. The semiconductor device according to claim 1, wherein the second semiconductor region includes a first region, and a second region provided between the first region and the first face, the second region is in contact with the first portion and the second portion, and the second region has a second conductivity type impurity concentration higher than a second conductivity type impurity concentration of the first region.

10. The semiconductor device according to claim 1, wherein a first length of the first portion in the first direction is larger than a second length of the second portion in the first direction.

11. The semiconductor device according to claim 1, wherein the second width is larger than the first width, and the second depth is larger than the first depth.

12. A semiconductor device comprising:
a semiconductor layer having a first face and a second face facing the first face, and including
a first semiconductor region of a first conductivity type,
a second semiconductor region of a second conductivity type provided between the first semiconductor region and the first face, and
a third semiconductor region of the first conductivity type provided between the second semiconductor region and the first face;
a first gate electrode provided on a first face side of the semiconductor layer and extending in a first direction parallel to the first face;
a second gate electrode provided on the first face side of the semiconductor layer, extending in the first direction, and provided in a second direction parallel to the first face and perpendicular to the first direction with respect to the first gate electrode;
a third gate electrode provided on the first face side of the semiconductor layer, extending in the first direction, and having the second gate electrode provided between the third gate electrode and the first gate electrode;
a first gate insulating layer provided between the first gate electrode and the semiconductor layer;
a second gate insulating layer provided between the second gate electrode and the semiconductor layer;
a third gate insulating layer provided between the third gate electrode and the semiconductor layer;
a first electrode provided on the first face side of the semiconductor layer and electrically connected to the third semiconductor region; and
a second electrode provided on a second face side of the semiconductor layer and electrically connected to the first semiconductor region, wherein
the first electrode includes a first portion and a second portion,
the first portion is provided between the first gate electrode and the second gate electrode,
the second portion is provided between the second gate electrode and the third gate electrode,
the second portion is provided in the second direction with respect to the first portion,
the first portion is in contact with the second semiconductor region and the third semiconductor region,
the second portion is in contact with the second semiconductor region and not in contact with the third semiconductor region,
the first portion is sandwiched between a part and another part of the semiconductor layer in the second direction,
the second portion is sandwiched between a part and another part of the semiconductor layer in the second direction, and
a second width of the second portion in the second direction is larger than a first width of the first portion in the second direction, or a second depth of the second portion is larger than a first depth of the first portion.

13. The semiconductor device according to claim 12, wherein
a portion of the semiconductor layer includes the third semiconductor region, a position of the portion in the second direction is a position between the first gate electrode and the second gate electrode, and
another portion of the semiconductor layer does not include the third semiconductor region, a position of the another portion in the second direction is a position between the second gate electrode and the third gate electrode.

14. The semiconductor device according to claim 12, further comprising:
an element region including the third semiconductor region; and
a termination region not including the third semiconductor region and surrounding the element region,
wherein the first portion is provided in the element region, and the second portion is provided in the termination region.

15. The semiconductor device according to claim 14, wherein
the first gate electrode is provided in the element region, and
the third gate electrode is provided in the termination region.

16. The semiconductor device according to claim 12, wherein
the semiconductor layer further includes a first trench provided on the first face side of the semiconductor layer and extending in the first direction, a second trench provided on the first face side of the semiconductor layer and extending in the first direction, and a third trench provided on the first face side of the semiconductor layer and extending in the first direction,
the first gate electrode is provided in the first trench,
the second gate electrode is provided in the second trench, and
the third gate electrode is provided in the third trench.

17. The semiconductor device according to claim 16, further comprising:
a first field plate electrode provided in the first trench and provided between the first gate electrode and the second face;
a second field plate electrode provided in the second trench and provided between the second gate electrode and the second face;
a third field plate electrode provided in the third trench and provided between the third gate electrode and the second face;
a first field plate insulating layer provided between the first field plate electrode and the semiconductor layer;
a second field plate insulating layer provided between the second field plate electrode and the semiconductor layer;
a third field plate insulating layer provided between the third field plate electrode and the semiconductor layer;
a first inter-electrode insulating layer provided between the first gate electrode and the first field plate electrode;
a second inter-electrode insulating layer provided between the second gate electrode and the second field plate electrode; and
a third inter-electrode insulating layer provided between the third gate electrode and the third field plate electrode.

18. The semiconductor device according to claim 12, wherein the second width is 1.2 times or more and 3 times or less the first width.

19. The semiconductor device according to claim 12, wherein the second depth is 1.2 times or more and 2 times or less the first depth.

20. The semiconductor device according to claim 12, wherein the second semiconductor region includes a first region, and a second region provided between the first region and the first face, the second region is in contact with the first portion and the second portion, and the second region has a second conductivity type impurity concentration higher than a second conductivity type impurity concentration of the first region.
